(19) United States
(12) Patent Application Publication
(10) Pub. No.: US 2026/0212079 A1
(43) Pub. Date: Jul. 23, 2026

(54) SYSTEMS, MEDIA, AND METHODS FOR METASURFACE DEVELOPMENT

(71) Applicant: 3M INNOVATIVE PROPERTIES COMPANY, St. Paul, MN (US)

(72) Inventors: Jennifer F. Schumacher, Woodbury, MN (US); Caitlin M. Race, Stillwater, MN (US); Yinong Wang, Woodbury, MN (US); Benjamin D. Zimmer, Hudson, WI (US); Heta Desai, Buford, GA (US); Cameron M. Fabbri, St. Paul, MN (US); Vahid Mirjalili, Ramsey, MN (US); Karthik Subramanian, St. Paul, MN (US); Niviru N. Wijayaratne, San Jose, CA (US)

(21) Appl. No.: 19/135,673

(22) PCT Filed: Dec. 8, 2023
(86) PCT No.: PCT/IB2023/062413

§ 371 Date: Jun. 4, 2025

Related U.S. Application Data
(60) Provisional application No. 63/432,034, filed on Dec. 12, 2022.

(51) Int. Cl. G06F 30/27

(52) U.S. Cl. CPC G06F 30/27

(57) ABSTRACT

The disclosure provides a device including at least one non-transitory computer-readable storage medium having instructions stored thereon, and processing circuitry coupled to the at least one non-transitory computer-readable storage medium, the processing circuitry being configured to execute the instructions to provide randomized data to a neural network, receive a metasurface design from the neural network, the metasurface design comprising one or more features, provide the metasurface design to a simulator, receive a performance value from the simulator, determine a loss value based on the performance value, update the neural network based on the loss value, and output the neural network to at least one of a user interface, an external device, or the at least one non-transitory computer-readable storage medium.

### BACKGROUND

Electromagnetic metasurfaces, also known as metasurfaces, can modulate or otherwise influence behavior of electromagnetic waves via deeply sub-wavelength structures. For example, optical metasurfaces can modulate behavior of wavelengths in or near the visible spectrum of wavelengths. Certain applications such as augmented reality films, in-display fingerprint reader films, switchable privacy films, LIDAR, and/or anti-photography films can utilize optical metasurfaces.

### SUMMARY

In one embodiment, the disclosure provides a device including at least one non-transitory computer-readable storage medium having instructions stored thereon, and processing circuitry coupled to the at least one non-transitory computer-readable storage medium, the processing circuitry being configured to execute the instructions to provide randomized data to a neural network, receive a metasurface design from the neural network, the metasurface design comprising one or more features, provide the metasurface design to a simulator, receive a performance value from the simulator, determine a loss value based on the performance value, update the neural network based on the loss value, and output the neural network to at least one of a user interface, an external device, or the at least one non-transitory computer-readable storage medium.

These and additional features provided by the embodiments described herein will be more fully understood in view of the following detailed description, in conjunction with the drawings.

### BRIEF DESCRIPTION OF THE DRAWINGS

FIG. 1 is a block diagram illustrating an exemplary system in which devices having communication capabilities are utilized and managed, according to aspects of this disclosure.

FIG. 2 is a block diagram illustrating an operating perspective of the system shown in FIG. 1.

FIG. 3 illustrates an exemplary metasurface according to aspects of this disclosure.

FIG. 4 illustrates an exemplary flow for training a generator to generate a metasurface design according to aspects of this disclosure.

FIG. 5 illustrates an exemplary generative network according to aspects of this disclosure.

FIG. 6 illustrates an exemplary maximally pixelated image according to aspects of this disclosure.

FIG. 7 illustrates a comparison of a first metasurface generated using a generator with no pixelation loss and a second metasurface generated using a generator trained with pixelation loss according to aspects of this disclosure.

FIG. 8 illustrates a comparison of a first metasurface generated using a generator with no solid loss and a second metasurface generated using a generator trained with solid loss according to aspects of this disclosure.

FIG. 9 illustrates an exemplary flow for conditioning a generator to generate a metasurface having one or more unknown physical parameter values according to aspects of this disclosure.

FIG. 10A illustrates an exemplary diagram of incident light at angle theta and corresponding reflection with an optical metasurface according to aspects of this disclosure.

FIG. 10B illustrates an exemplary diagram of incident light at angle theta and corresponding transmission with an optical metasurface according to aspects of this disclosure.

FIG. 11 illustrates an exemplary flow for training a generator using a machine learning-based physical property estimator according to aspects of this disclosure.

FIG. 12A illustrates an exemplary metasurface design with discontinuous features according to aspects of this disclosure.

FIG. 12B illustrates a concatenation of copies the metasurface design in FIG. 12A.

FIG. 12C illustrates an exemplary metasurface design including the discontinuous features of FIG. 12A aggregated to form a continuous feature according to aspects of this disclosure.

FIG. 13 illustrates an exemplary flow of a similarity function according to aspects of this disclosure.

FIG. 14 illustrates an exemplary process for training a metasurface design generator according to aspects of this disclosure.

FIG. 15 illustrates an exemplary process for generating a metasurface design according to aspects of this disclosure.

FIG. 16 illustrates exemplary manufacturability constraints overlaid on a metasurface design according to aspects of this disclosure.

FIG. 17 illustrates an exemplary flow for training a generative adversarial network (GAN) to generate metasurface designs according to aspects of this disclosure.

FIG. 18 illustrates an exemplary process for training a GAN according to aspects of this disclosure.

FIG. 19 illustrates an exemplary process for generating a metasurface design using a GAN according to aspects of this disclosure.

FIG. 20 illustrates an exemplary raster surface representation of a metasurface design according to aspects of this disclosure.

FIG. 21 illustrates an exemplary non-raster surface representation of a metasurface design according to aspects of this disclosure.

FIG. 22 illustrates an exemplary flow for training a generator to generate metasurface designs using a rasterization technique according to aspects of this disclosure.

FIG. 23 illustrates an exemplary process for training a generator to generate metasurface designs using a rasterization technique according to aspects of this disclosure.

FIG. 24 illustrates an exemplary process for generating metasurface designs using a rasterization technique according to aspects of this disclosure.

FIG. 25 illustrates an exemplary process for generating metasurface designs using a genetic algorithm technique according to aspects of this disclosure.

FIG. 26 illustrates an exemplary process for generating metasurface designs and associated ray tracing data according to aspects of this disclosure.

### DETAILED DESCRIPTION

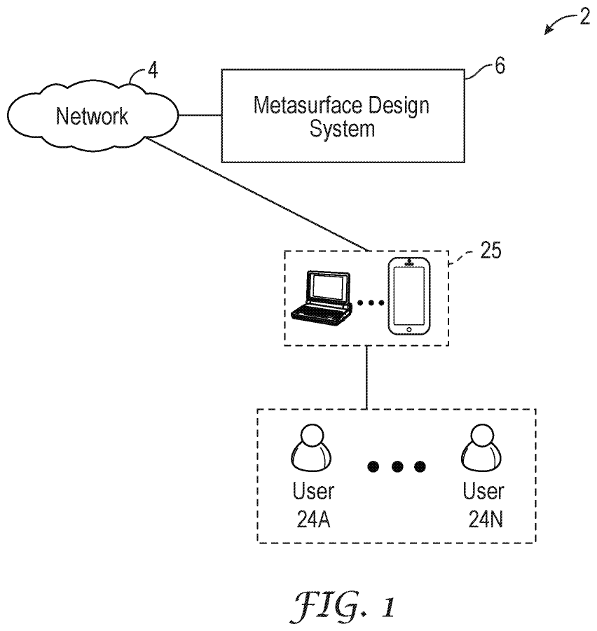

FIG. 1 is a block diagram illustrating an exemplary system 2 in which devices having communication capabilities are utilized and managed, according to aspects of this disclosure. System 2 includes metasurface design system (MDS) 6, which is configured to provide metasurface design functionalities to computing devices 25 in accordance with aspects of this disclosure. As described herein, MDS 6 enables authorized users (e.g., one of users 24A-24N) to generate metasurface designs. By interacting with MDS 6, design professionals can, for example, generate metasurface designs, train metasurface generators, simulate metasurface designs, and/or generate ray tracing metrics. In general, MDS 6 provides design and simulation functionalities.

As shown in the example of FIG. 1, system 2 represents a computing environment in which a computing device (e.g., one of the computing devices 25) can electronically communicate with MDS 6 via one or more computer networks 4. The network 4 can include one or more wired and/or wireless connections. For example, the network 4 can include connections defined by the Institute of Electrical and Electronics Engineers (IEEE) 802.11 family of protocols, ZigBee® network connections (conforming to the IEEE 802.15 family of standards), 5G® network connections, short-range wireless (e.g., Bluetooth® and/or near-field communication (NFC)) connections, Ethernet® connections, and/or coaxial connections.

One or more of users 24A-24N may use computing devices 25 to interact with MDS 6 via network 4. For example, the end-user computing devices 25 may include, be, or be part of laptops, desktop computers, mobile devices such as tablet computers or so-called “smartphones,” and the like.

Users 24 (e.g., 24A-24N) interact with MDS 6 to generate metasurface designs, train metasurface generators and/or models, simulate metasurface designs, generate metasurface design information (e.g., ray tracing data), and/or utilize applications related to metasurface designs. For example, users 24 may generate a metasurface design to satisfy one or more design parameters. In addition, users 24 may interact with MDS 6 to simulate metasurface designs and/or generate ray tracing data to gauge the performance of one or more metasurface designs. MDS 6 may enable users 24 to train a generator and/or model to create metasurface designs. In some examples, MDS 6 may present a web-based interface via a web server (e.g., an HTTP server) or client-side applications may be deployed for devices of computing devices 25 used by users 24, such as desktop computers, laptop computers, mobile devices such as smartphones or tablets, or the like.

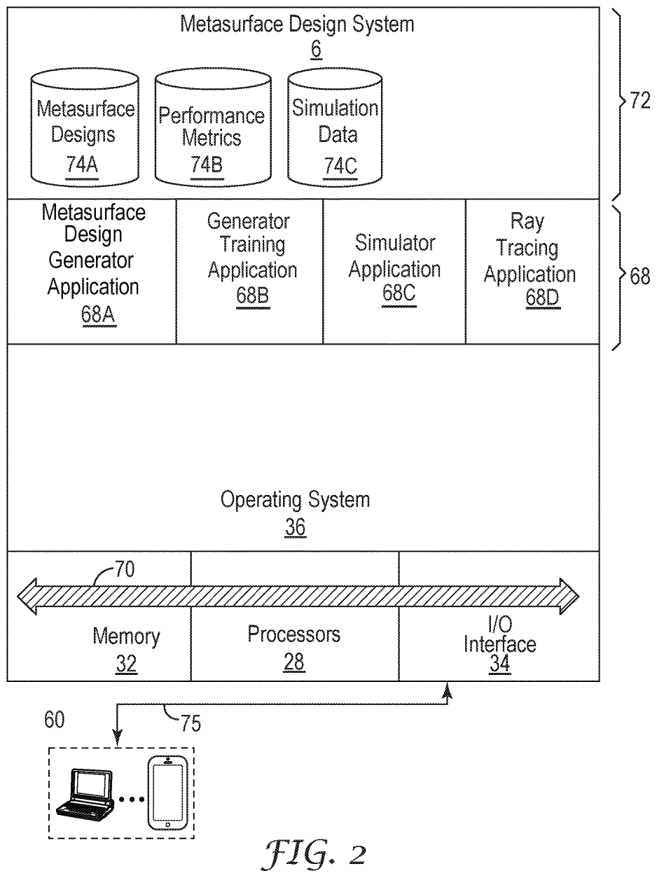

FIG. 2 is a block diagram illustrating an operating perspective of one example implementation of MDS 6 shown in FIG. 1. While FIG. 2 shows one implementation of MDS 6 that is consistent with aspects of this disclosure, it will be appreciated that other architectures (whether single-device or distributed architectures) of MDS 6 are consistent with aspects of this disclosure, as well.

In the example of FIG. 2, MDS 6 includes one or more processors 28 and memory 32. In some examples, memory 32 and processors 28 may be integrated into a single hardware unit, such as a system on a chip (SoC) or integrated circuit (IC). Each of processors 28 may comprise one or more of a multi-core processor, a controller, a digital signal processor (DSP), an application specific integrated circuit (ASIC), a field-programmable gate array (FPGA), processing circuitry (e.g., fixed function circuitry, programmable circuitry, or any combination of fixed function circuitry and programmable circuitry) or equivalent discrete logic circuitry or integrated logic circuitry. Memory 32 may include any form of memory for storing data and executable software instructions, such as random-access memory (RAM), read-only memory (ROM), programmable read only memory (PROM), erasable programmable read-only memory (EPROM), electronically erasable programmable read only memory (EEPROM), and flash memory.

Memory 32 and processor(s) 28 provide a computer platform for executing operation system 36. In turn, operating system 36 provides a multitasking operating environment for executing one or more software components 68. As shown, processors 28 connect via an input/output (I/O) interface 34 to external systems and devices, such as to interfaces deployed at computing devices 60, and the like. I/O interface 34 may incorporate network interface hardware, such as one or more wired and/or wireless network interface controllers (NICs) for communicating via communication channel 75, which may represent one or more network-enabled communicative connections, such as one or more packet-switched networks. Bus 70 provides inter-component connectivity between processors 28, memory 32, and I/O interface 34 in the implementation shown in FIG. 2. Bus 70 may represent a half-duplex or full-duplex bus that provides data transfer capabilities between two or more of processors 28, memory 32, I/O interface 34, and/or any other hardware components of MDS 6. Bus 70 may represent a system bus or a computer bus of various types, including one or more bus networks. Regardless of the topology implemented, bus 70 may, in various examples, incorporate various types of inter-component connectivity hardware such as those conforming to any of first generation, second generation, third generation, or fourth generation bus or bus network technology as set forth by the IEEE, and/or other bus or bus network technologies defined in developing or later-adopted standards.

Software components 68 of MDS 6, in the particular example of FIG. 2, include metasurface design generator application 68A, model training application 68B, simulator application 68C, and ray tracing application 68D. In some example approaches, one or more of software components 68 represent executable software instructions that may take the form of one or more software applications, software packages, software libraries, hardware drivers, and/or Application Program Interfaces (APIs). Moreover, any of software components 68 may output data and/or receive data via I/O interface 34.

Aspects of memory 32 that provide non-volatile storage and/or long-term storage support local storage of data repositories 72. In the example of FIG. 2, data repositories 72 include metasurface designs 74A, performance metrics 74B, and simulation data 74C. One or more of software components 68 may invoke processors 28 and memory 32 to access one or more of data repositories 72 to retrieve data for various purposes, such as comparison, processing, and relaying, and/or viewing metasurface designs, performance metrics, and/or simulation data. In some examples, software components 68 may implement read/write capabilities with respect to data repositories 72, such as to access and use information available from data repositories 72 and/or to modify information currently stored to data repositories 72. In implementations in which MDS 6 represents a distributed computing system, one or more of data repositories 72 may be positioned at a remote location from processors 28, and software components 68 may, in these implementations, access data repositories 72 using NIC hardware of I/O interface 34.

Metasurface design generator application 68A operates as an application for generating metasurface designs using a generator, model (e.g., a machine learning model), and/or another generation technique (e.g., a genetic algorithm generation technique). As will be described below, the metasurface design generator application 68A can generate metasurface designs for metasurfaces to be used in various applications (e.g., optical metasurfaces for augmented reality films, in-display fingerprint reader films, switchable privacy films, LIDAR, and/or anti-photography films). Model training application 68B operates as an application for training machine learning models such as neural networks and/or generators to generate metasurface designs. In some examples, the model training application 68B can output trained generators and/or models to the metasurface design generator application 68A. The simulator application 68C operates as an application for simulating metasurface designs to generate performance metrics for a given metasurface design.

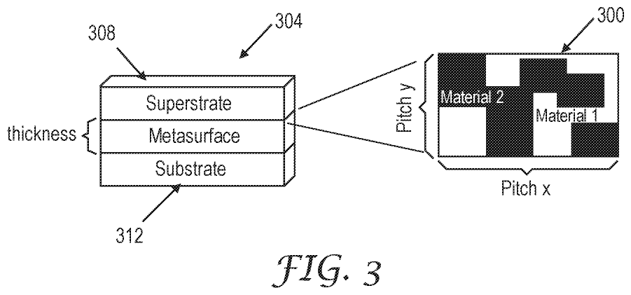

FIG. 3 illustrates an exemplary metasurface 300 according to aspects of this disclosure. As shown, the metasurface 300 is included in a metasurface device 304. The metasurface 300 can be arranged between a superstrate 308 and a substrate 312. In some examples, the metasurface 300 can be exposed to air on one or more sides, meaning the superstrate 308 and/or the substrate 312 can be air. In some examples, the superstrate 308 and/or the substrate 312 can include one or more solid materials such as a polymer (e.g., polyethylene terephthalate and/or polyvinyl butyral) and/or silica glass. In some examples, the superstrate 308 and/or the substrate 312 can be a uniform material having a predetermined thickness. In some examples, the superstrate 308 and/or the substrate 312 can include multiple layers of materials each having a predetermined thickness. In some examples, the superstrate 308 and/or the substrate 312 can be the same. The metasurface 300 can be of a predetermined thickness, and may include two materials arranged in a way that produces a desired effect (e.g., enhancing transmission efficiency for a certain wavelength and incident angle). Each material included in the metasurface 300 can extend throughout the entire thickness of the metasurface 300. While the metasurface 300 is a three-dimensional material, the materials may be arranged variably along an x-axis and a y-axis of the metasurface 300 without variation in how far the materials extend along a z-axis. Thus, the arrangement of the materials can be considered a two-dimensional problem, even though the thickness of the materials (and by extension, the metasurface 300) is also a factor in metasurface construction.

Physical characteristics of the metasurface device 304 can include refractive indices of materials included in the superstrate 308 and/or the substrate 312, dispersive refractive indices of the materials included in the metasurface 300, the thickness of the metasurface 300, and the pitches of the metasurface 300. In some examples, if a desired thickness and/or pitch for the metasurface 300 is unknown, thickness and/or pitch can be conditioned during training. In some examples, mirror symmetries of the structures included in the metasurface 300 can be defined as having symmetry about the x-axis, symmetry about the y-axis, symmetry about the xy-plane, or no symmetry. Metasurface designs that utilize symmetry can reduce computational time of training by up to about fifty percent.

Optical characteristics of the metasurface device 304 can include a position of a light source in relation to the superstrate 308 and/or the substrate 312, an optical mode (e.g., reflect, transmit, and/or absorb), a polarization (e.g., transverse electric, transverse magnetic, and/or unpolarized), an optical order (one order or multiple orders), one or more wavelengths, one or more polar angles, one or more azimuthal incident angles, and/or a desired optical efficiency. Generators of this disclosure may be trained to generate metasurfaces that satisfy one or more sets of specifications defining the optical characteristics. In some examples, rather than receiving optical order information as training data, the generators of this disclosure may be trained with one or more user-specified diffraction angles.

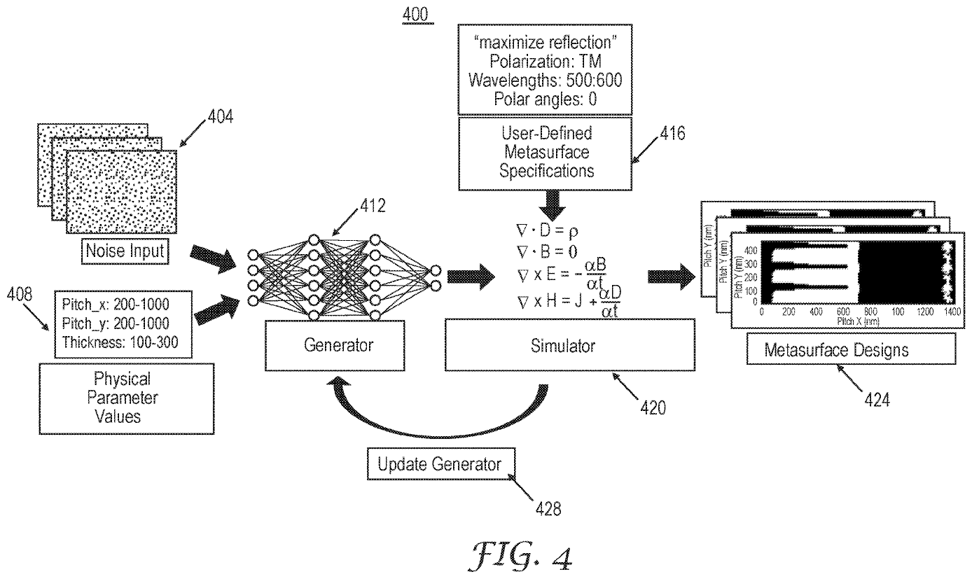

FIG. 4 illustrates an exemplary flow 400 for training a generator 412 to generate a metasurface design according to aspects of this disclosure. The flow 400 can include providing noise inputs 404 to the generator 412. The noise inputs 404 can be randomized data. The noise inputs 404 can be predetermined or selected by a user before training the generator 412. In some examples, the flow 400 can include receiving a selection of a sample distribution of the noise inputs 404 (e.g., uniform and/or gaussian) and a random seed for the noise inputs 404 from a user. In some examples, the generator training application 68B can train the generator 412 using randomized noise, so no training data (e.g., exemplary metasurface design information) is required, thereby providing an advantage over other approaches that may require a large set of training data to properly train a generator to generate metasurface designs. The flow 400 can utilize the randomized noise and feedback from a simulator technique to train the generator 412 via an adjoint method technique.

The generator 412 can include a generative network. In some examples, the generative network can be a neural network such as a convolutional neural network (CNN). In some examples, the flow 400 can include providing physical parameter values 408 to the generator 412. In some examples, the physical parameter values 408 can be referred to as condition parameter values. The physical parameter values 408 can include one or more values and/or ranges with which that generated metasurface designs may be configured to comply (e.g., specifications for a predetermined application). In some examples, the physical parameter values 408 can include physical parameter values such as thickness values (e.g., z-axis length), pitch values for width (e.g., x-axis length), and/or pitch values for height (e.g., y-axis length). In some examples, the physical parameters can include a range of values for one or more of the x-axis pitch, the y-axis pitch, or the z-axis thickness.

Using the noise inputs 404 and/or the physical parameter values 408, the generator 412 can generate a metasurface design 424. In some examples, the generator 412 can generate multiple instances of metasurface design 424. The metasurface design 424 can include manufacturing data that allows a metasurface to be manufactured based on the metasurface design 424. In other words, the metasurface design 424 can be considered a blueprint for the manufactured metasurface. In some examples, the metasurface design 424 can include an x-axis pitch value, a y-axis pitch value, a z-axis thickness value, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design 424 can include a raster surface representation of a metasurface.

The flow 400 can include providing one or more instances of metasurface design 424 generated by the generator 412 to a simulator 420. The simulator 420 can simulate a respective performance of each instance of metasurface design 424. The simulator 420 can generate one or more performance metric values such as a reflection value, a transmission value, or an absorption value for one or more wavelengths, angles, and/or orders. In some examples, the simulator 420 can include a rigorous coupled-wave analysis (RCWA) simulator such as RETICOLO or Stanford Stratified Structure Solver (S4), and/or a finite-difference time-domain (FDTD) simulator such as Lumerical or Meep. In some examples, the generator 412 can provide a count of Fourier orders for a simulation as an input hyperparameter to the simulator 420. In some examples, the simulator 420 can simulate desired optical characteristics (e.g., polarization and/or mode).

The flow 400 can include calculating one or more loss values based on the performance metric values and one or more user-defined metasurface specifications 416. The flow 400 can include updating the generator 428 based on the one or more calculated loss values. In some examples, the flow 400 can include calculating the loss values based on an adjoint method to obtain gradients for a given metasurface design 424. The flow 400 can also include calculating a base loss value based on the gradients using a base loss function such as a gaussian, sigmoid, or soft plus technique. In some examples, the flow 400 can weight wavelengths, angles, and/or goal efficiencies included in each metasurface specification 416 according to a triangle, gaussian, or uniform distribution, where the weights are applied, along with any lambda coefficients, with the final summation of the loss values. In some examples, the flow 400 can include calculating loss function values using one or more loss functions each including a lambda coefficient, each lambda coefficient being associated with a start value and an end value at designated steps. In some examples, the flow 400 can include calculating loss function values using one or more loss functions each including a lambda coefficient and a sigma coefficient, each of the lambda coefficient and the sigma coefficient being associated with a start value and an end value at designated steps.

In some examples, the flow 400 can include other loss functions. In some examples, the flow 400 can include calculating a cosine penalty. The cosine penalty can be included as a loss value to increase variability in generated metasurface designs. In some examples, the flow 400 can include calculating a binarization loss value, which may assist in how a given metasurface is binarized to two distinct materials over multiple steps. In some examples, the flow 400 can include calculating an additional loss function value to suppress optical orders not of interest in the specification.

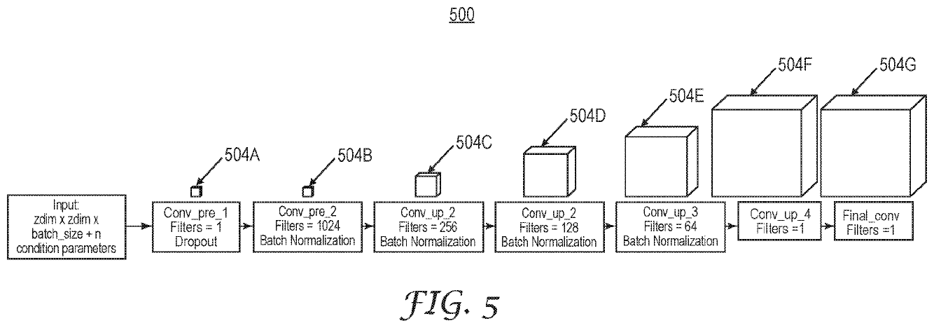

Referring now to FIG. 4 as well as FIG. 5, an exemplary generative network 500 according to aspects of this disclosure is shown. In some examples, the generative network 500 can be included in the generator 412 of FIG. 4. In some examples, the generative network 500 can be a neural network such as a CNN. The generative network 500 can include a number of convolutional layers 504A-G. The generative network 500 can include a number of Leaky ReLU activations. The generative network 500 can also include periodic padding on each of the convolutional layers 504A-G. The periodic padding can build periodicity into the generative network 500. The generative network 500 can generate metasurfaces used as tiles in one or more periodic surfaces, so building periodicity into the generative network 500 can improve performance in the generated metasurfaces. In some examples, the architecture of the generative network 500 can include various number of layers, filter sizes, and/or upscaling, and generator training application 68B can train the generative network 500 using various network hyperparameters such as learning rate, batch size, and/or number of steps.

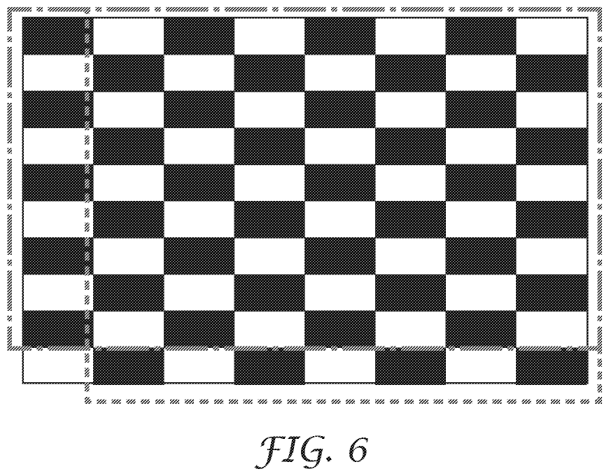

Referring to FIG. 4 as well as FIG. 6, an exemplary maximally pixelated image 600 according to aspects of this disclosure is shown. As described above, the flow 400 can include calculating a pixelation loss value and/or a solid loss value. To aid in the manufacturability of metasurfaces, metasurface features can include size and/or gap dimensions. In testing, it was found that generators (e.g., CNNs) tend to deliver better data precision at pixel resolutions that represent feature sizes that are too small to be reliably reproduced in large scale production. Thus, the generator training application 68B can introduce pixelation losses and/or solid losses to train generative network 500 to generate metasurface designs that are more easily manufacturable.

As shown in FIG. 6, highly pixelated metasurfaces appear in a checkerboard format, and can be treated as “noise.” The generator training application 68B can introduce a pixelation loss to penalize designs having a large sum of neighboring pixel absolute differences in a metasurface design. The generator training application 68B can calculate the pixelation loss based on the sum of neighboring pixel absolute differences in the metasurface design.

By minimizing the sum of neighboring pixel absolute differences, noise in the image can be reduced, thereby reducing the checkerboard appearance, and improving the manufacturability of the devices by having larger, more separated features. Thus, the pixelation loss is configured to penalize metasurface designs that include a large number of neighboring pixel absolute differences.

Testing showed that the generators may generate metasurface designs in which some or all of the surfaces being generated are “solid,” in which the device consists of a single uniform material layer, as opposed to a combination of both low and high refractive index materials. In order to train generators to not produce these types of surfaces, the generator training application 68B can calculate a solid loss.

As shown in FIG. 6, the refractive index of each pixel included in a metasurface design is represented visually in black or white, which is a visual proxy for an effective refractive index, bounded by the range [−1, 1]. The generator training application 68B can calculate the solid loss as a square of a sum of pixel values included in the metasurface design divided by a product of dimensions of the metasurface design as shown in Equation 1 below.

$$solid loss = {( \frac{{\sum }_{i}^{n} {\sum }_{j}^{m} surface\_batch}{n * m} )}^{2} \qquad ( 1 )$$

In Equation 1, a surface batch is of size (batch, n, m), where batch is the number of metasurface designs and n and m are the dimensions of a surface matrix, with values bounded by range [−1, 1].

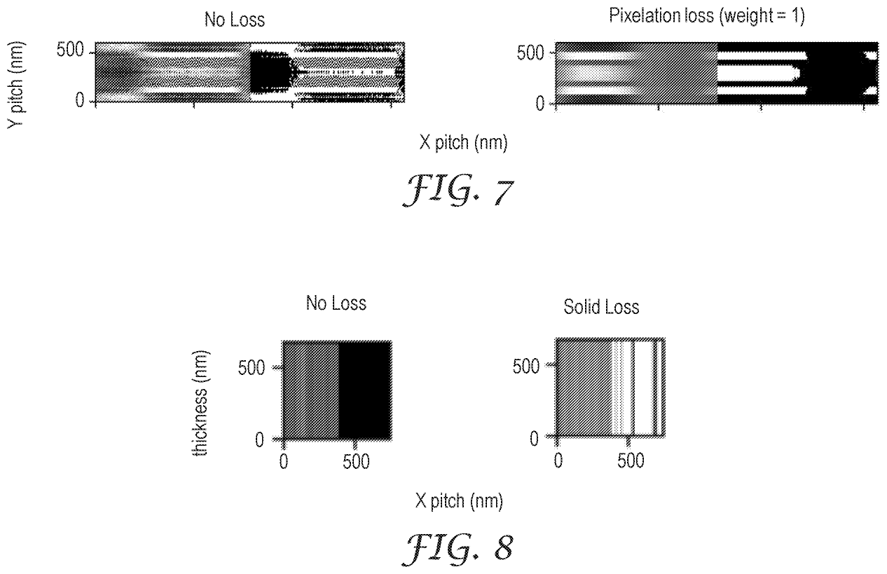

FIG. 7 illustrates a comparison of a first metasurface generated using a generator with no pixelation loss and a second metasurface generated using a generator trained with pixelation loss according to aspects of this disclosure. As shown in FIG. 7, there is a discernible difference between metasurfaces generated by generators with and without pixelation loss. The first metasurface includes many small checkerboard features which do not disappear during training, and which are difficult if not impossible to manufacture on a large scale for roll-to-roll applications. In the second metasurface, there are significantly larger features and gaps without the checkerboard patterns. In testing, it was noted that increasing the impact of the pixelation loss beyond a coefficient of one may result in larger gaps between features and more unpatterned space. Thus, too large of a coefficient for pixelation loss can lead to completely solid devices.

FIG. 8 illustrates a comparison of a first metasurface generated using a generator with no solid loss and a second metasurface generated using a generator trained with solid loss according to aspects of this disclosure. As shown in FIG. 8, the inclusion of the solid loss when training a generator has a noticeable effect on the surfaces generated. Uniform surfaces are no longer generated by the network. The first metasurface represents a training run that has entered a degenerative state of generating primarily solid devices. The solid loss provides a metric that measures the prevalence of solid devices in the batch and assists in training generators to avoid this undesired state.

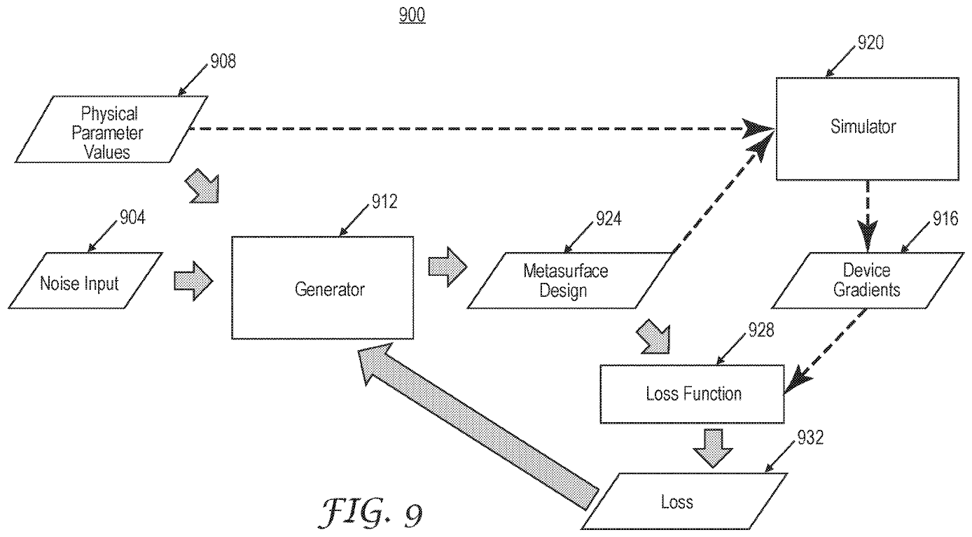

FIG. 9 illustrates an exemplary flow 900 for conditioning a generator to generate a metasurface having one or more unknown physical parameter values according to aspects of this disclosure. A user may not know what specific physical parameter values the metasurface should have, and the flow 900 can help determine one or more potential physical parameter values the metasurface can have to satisfy requirements for a particular metasurface device. In some examples, the generator can be conditioned based on one or more user-provided ranges of values (e.g., a range of thickness values), such as by configuring the generator to sample the one or more ranges of values during training.

One approach to training generators is the adjoint method. However, the adjoint method is limited to calculating gradients with respect to only a specific aspect of a metasurface design. Specifically, the adjoint method is limited to calculating gradients for material at each location of the metasurface design. Variables of interest that the adjoint method cannot account for include the overall physical dimensions of the metasurface device. The flow 900 can condition a generator while incorporating gradients related to the metasurface while sampling a range of physical dimensions of the metasurface designs.

In some examples, the flow 900 can include providing noise input 904 and sampled physical parameter values 908 to a generator 912. In some examples, the physical parameter values 908 can include pitch values and/or thickness values. In some implementations, the noise input 904 and the generator 912 can be substantially the same as noise inputs 404 and the generator 412 in FIG. 4, respectively. The flow 900 can include receiving a metasurface design 924 generated by the generator 912. In some examples, the metasurface design 924 can be substantially the same as the metasurface design 424 in FIG. 4.

The flow 900 can include providing the physical parameter values 908 and the metasurface design 924 to a simulator 920. In some example, the simulator 920 can be substantially the same as the simulator 420 in FIG. 4. The flow 900 can include receiving device gradients 916 from the simulator 920. The device gradients 916 can include gradients associated with one or more pitch values and/or thickness values. Specifically, the device gradients 916 can be associated with the physical parameter values 908 because the device gradients 916 reflect overall performance of the metasurface device having certain refractive index values and the physical parameter values 908, even though the physical parameter values 908 are not differentiable. The flow 900 can include providing device gradients 916 and the metasurface design 924 to a loss function 928. In some examples, the loss function can include one or more of the loss functions described above. The loss function 928 can calculate one or more loss values 932, and the generator training application 68B can update the generator 912 based on the loss values 932.

By providing parameters such as thickness and pitch values to the simulator, it is possible to condition the generator on those thickness and pitch values. From one simulation to the next, as simulation parameters change, generator output will be evaluated differently. In this case, simulation parameters include two types. Specifically, the two types are (i) simulation parameters that describe desired behavior of the device (e.g., the device should be efficient across multiple wavelengths or angles) as opposed to (ii) parameters that describe unknown qualities of the metasurface device that are also not differentiable (e.g., having a specific pitch and thickness). The parameters that describe unknown qualities of the metasurface device can be conditioned by sampling the parameters during training, then the generator training application 68B can present a user with a list of selectable options that include an appropriate device for a particular application. In some examples, each selectable option can include one or more physical parameter values and/or performance parameter values.

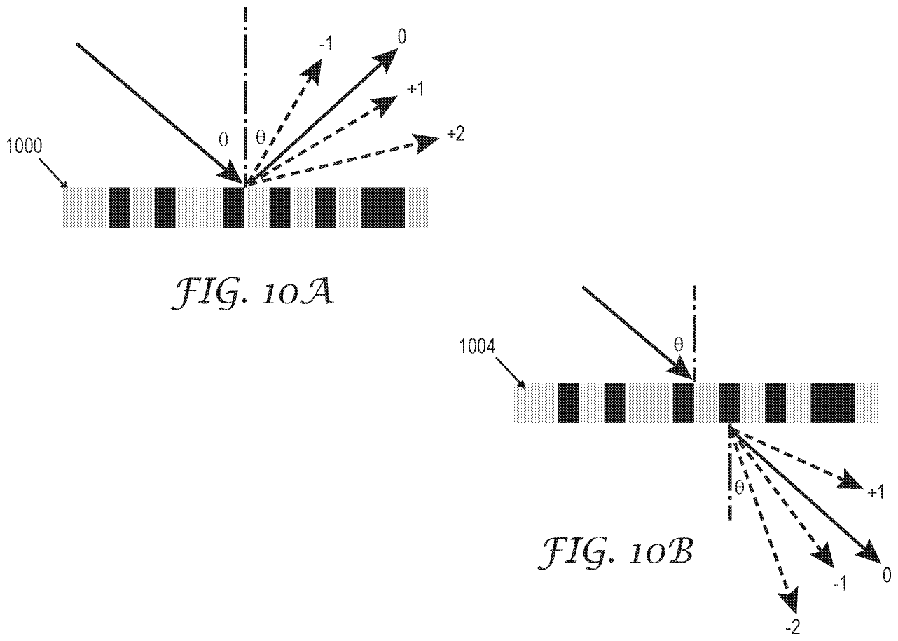

FIG. 10A illustrates an exemplary diagram of incident light at angle theta and corresponding reflection with an optical metasurface according to aspects of this disclosure. FIG. 10B illustrates an exemplary diagram of incident light at angle theta and corresponding transmission with an optical metasurface according to aspects of this disclosure.

Referring now to FIG. 4 as well as FIGS. 10A and 10B, a technique for integrating performance specifications for multiple orders into the metasurface specifications 416 is described. More specifically, FIGS. 10A and 10B illustrate multiple orders of refracted light and transmitted light, respectively. Equation 2 below can be used to specify the performance of all non-zero orders.

$$orders = ! [ 0 ] \qquad ( 2 )$$

For example, a user could choose to maximize diffuse reflection by selecting the zero order and indicating a negation of the selection as specified in Equation 2. Reflected light at non-zero orders may be referred to as diffuse. Equation 3 below can specify performance of all non-zero orders except any explicitly stated order.

$$orders = ! [ 0 , x ] \qquad ( 3 )$$

In some examples, the generator training application 68B can provide a user an option to select x in Equation 3. In Equation 3, x can include one or more non-zero orders that, for a specified performance metric, performance is penalized. For example, a user may wish to specify all orders except the second order for maximizing diffuse reflection, while penalizing diffuse reflection in the second order. By defining the selection of orders in this way, a user does not need to specify every single non-zero order (of which there could be hundreds or thousands) ahead of executing a simulation. In some examples, the simulation can be a RCWA simulation. In some examples, diffraction efficiencies generated using Equation 2 and/or Equation 3 can be aggregated in a loss function configured to maximize a sum of diffraction efficiencies across the specified orders. In some examples, the loss function can be configured to minimize diffraction efficiencies for specified orders depending on the source angle or wavelength. For example, a user may want to maximize reflection at all non-zero orders. In some examples, a user may choose to maximize transmission at a number of non-zero orders. A user can select orders to be maximized and/or penalized using equations 2 and/or 3 in metasurface specifications 416 in FIG. 4.

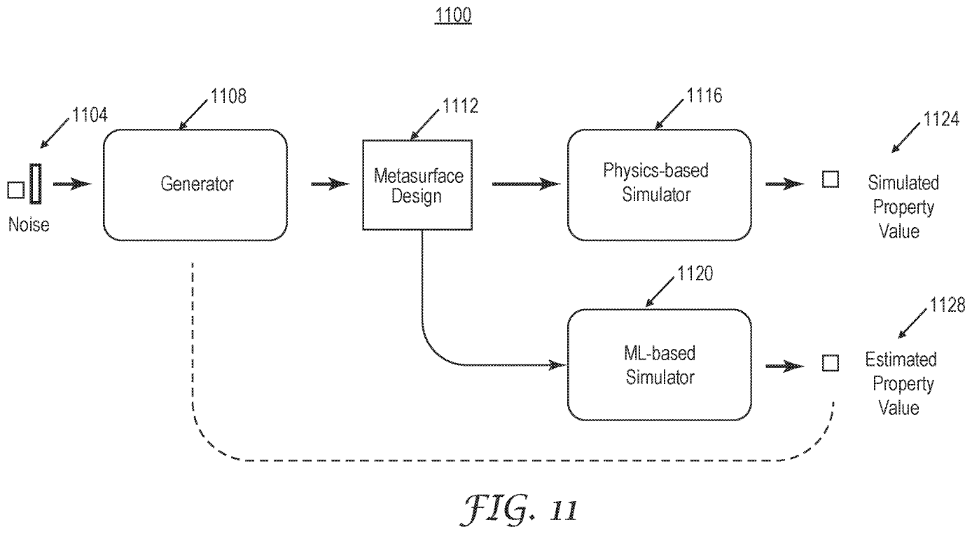

FIG. 11 illustrates an exemplary flow 1100 for training a generator 1108 using a machine learning-based physical property estimator 1120 according to aspects of this disclosure. In some examples, the generator 1108 can be the generator 412 in FIG. 4. In some examples, the flow 1100 can include providing noise inputs 1104 to the generator 1108, receiving a metasurface design 1112 from the generator 1108, and providing the metasurface design 1112 to a physics-based simulator 1116 and the machine learning-based physical property estimator 1120. In some examples, the physics-based simulator 1116 can be the simulator 420 in FIG. 4. The physics-based simulator 1116 can be configured to generate a simulated property value 1124 for a predetermined property such as an efficiency. The machine learning-based physical property estimator 1120 can be a neural network that can be to generate an estimated property value 1128. The estimated property value 1128 and the simulated property value 1124 can each be values for a common physical property of the metasurface design 1112, such as a performance parameter. In some examples, the performance parameter can be a reflection value, a transmission value, and/or an absorption value for one or more wavelengths, angles, and/or orders.

One advantage of the machine learning-based simulator 1120 and the estimated property value 1128 is that the generator 1108 can be trained without relying on gradients of the properties with respect to the design parameters obtained from physical simulation. The flow 1100 includes two neural networks, one as the generator 1108 and another as the physics-based simulator 1116. Furthermore, the flow 1100 can include the generator training application 68B training both the generator 1108 and the ML-based simulator 1120 without pre-existing data for training because the generator 1108 and the ML-based simulator 1120 are trained on the metasurface designs 1112 generated by the generator 1108 and assessed by the physics-based simulator 1116. Thus, the generator 1108 can be trained to generate metasurface designs without a gradient-based method (e.g., an adjoint technique). In some examples, the simulator 420 in FIG. 4 can include both the physics-based simulator 1116 and the machine learning-based simulator 1120, and the simulated property value 1124 and the estimated property value can be used in updating the generator 428 in the flow 400 in FIG. 4.

Referring to FIGS. 4, 9, and 11, a technique for generating metasurface designs having a predetermined absorption is discussed. When training a generator using a physics-based simulator (e.g., the simulator 420 in FIG. 4, the simulator 920 in FIG. 9, and/or the physics-based simulator 1116 in FIG. 11), the simulator can generate a gradient function via an adjoint technique. The adjoint technique can include two complementary simulations of light in a metasurface design generated by the generator. First, the simulator simulates light propagating in a forward direction with specified direction and polarization and exiting the metasurface design. Second, the simulator simulates light propagating backwards with direction and phase determined by exiting light properties of the light propagating in the forward direction.

For properties such as transmission and reflection, the two-step adjoint method can function as described above. However, for absorption, the simulator cannot simulate light propagating in the backwards direction because the absorbed light has no exiting direction derived from the initial light propagating in the forward direction. Thus, the gradient function cannot be generated to train a generator to generate metasurface designs for a specified absorptive metasurface characteristic.

Absorption may be a desirable trait to maximize or minimize for certain types of metasurface devices. Minimizing absorption may be useful for metasurfaces that are intended to interact only with specific wavelengths for augmented reality displays or to be minimally visible in their environment while interacting with light outside of the visible spectrum. Maximizing absorption is useful for filters and shielding to specific wavelengths, directions, or polarizations.

To generate a metasurface design having a target absorption efficiency x_{A}, the target efficiency x_{A} can be replaced with specifications for transmission and reflection, each to all diffraction orders, which have inverted targets x_{T} and x_{R}, respectively. Then, a training process can generate a gradient that is effectively an absorption gradient, but achieved through an adjoint method to train the generator.

$$T + R + A = 1 \qquad ( 4 )$$

In Equation 4 above, A, T, and R, represent the efficiencies of transmission and reflection to all diffraction orders, and absorption, of the metasurface to incident light with any specified properties or range of properties. In other words, one hundred percent of light is either transmitted, reflected, or absorbed.

A training process can update a generator based on whether or not the target absorption has been met. If the goal is to maximize A and A<x_{A}, the training process continues to seek metasurface designs which increase A, taking into account other unmet specifications. If A>x_{A}, then other specifications whose targets haven't been met drive the updates of the generator as opposed to maximizing A. In some examples, generating inverted targets x_{T} and x_{R}, a user can set targets so that optimization of A is switched “off” when there is a possibility that the target has been met by T and R or it is guaranteed that the target has been met by T and R. To guarantee that the target has been met by T and R, the target inversion has to be handled separately for maximization and minimization as follows in Equations 5-10 and 11-15, respectively:

### Minimization of Absorption

$$A < {x}_{A} \qquad ( 5 )$$

$$A = 1 - T - R \qquad ( 6 )$$

$$T + R > 1 - {x}_{A} \qquad ( 7 )$$

The losses for T and R are handled agnostically of one another, and x_{T} is set so that the condition A<x_{A} is true if and only if T>x_{T}, therefore the limiting case of a minimum contribution from R, R=0 can be assumed.

$$T > 1 - {x}_{A} \qquad ( 8 )$$

$${x}_{T} = 1 - {x}_{A} \qquad ( 9 )$$

By the same argument x_{R} is derived,

$${x}_{R} = 1 - {x}_{A} . \qquad ( 10 )$$

### Maximization of Absorption

$$A > {x}_{A} \qquad ( 11 )$$

$$A = 1 - T - R \qquad ( 12 )$$

$$T + R < 1 - {x}_{A} \qquad ( 13 )$$

x_{T} is set so that the condition A>x_{A} is true if and only if T<x_{T}, therefore the limiting case of a maximum contribution from R, R=1 can be assumed.

$$T + 1 < 1 - {x}_{A} \qquad ( 14 )$$

The condition isn't met; there is no value of T, agnostic of R, for which it can be guaranteed that A>x_{A}. Therefore, the target is set to its physical lower limit.

$${x}_{T} = 0 = {x}_{R} \qquad ( 15 )$$

Thus, the training process can generate one or more loss values for minimizing and/or maximizing absorption for one or more wavelengths, angles, and/or orders using Equations 5-10 and 11-15, respectively.

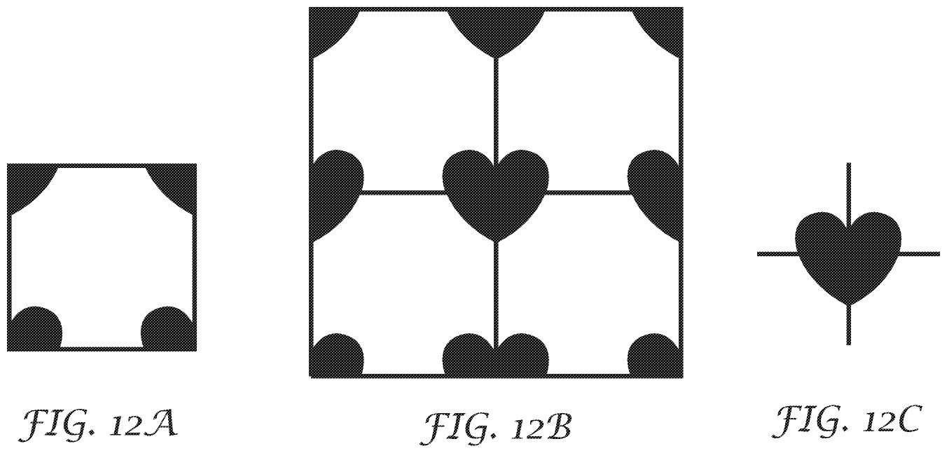

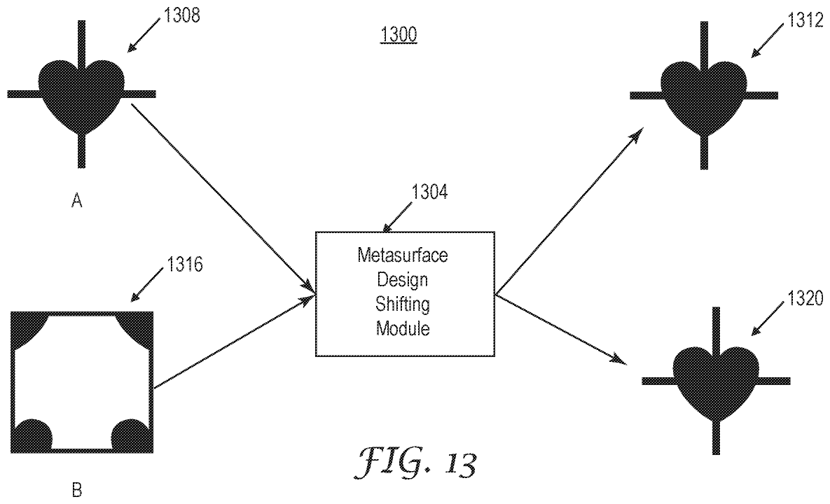

Referring now to FIGS. 12A, 12B, and 12C, FIG. 12A illustrates an exemplary metasurface design with discontinuous features according to aspects of this disclosure. FIG. 12B illustrates a concatenation of copies of the metasurface design in FIG. 12A. FIG. 12C illustrates an exemplary metasurface design including the discontinuous features of FIG. 12A aggregated to form a continuous feature according to aspects of this disclosure. In some examples, a generator (e.g., generator 412 in FIG. 4) may produce designs with discontinuous features. Without accounting for the discontinuous features, a generator may generate copies of the same metasurface designs, where the only difference between designs is the periodicity of the features, thereby suppressing metasurface diversity. By shifting discontinuous features to form continuous features, the periodicity of metasurface designs can be accounted for.

In some examples, a flow (e.g., the flow 400 in FIG. 4) can include aggregating discontinuous features to form a largest possible feature. The largest possible feature may be positioned in the center of a metasurface design. To shift the largest feature to the center, the flow can include generating four copies of a discontinuous featured surface (e.g., the metasurface design in FIG. 12A) and generating a concatenation the four copies of the metasurface (e.g., the concatenation in FIG. 12B). Thus, the flow can include concatenating multiple copies of the discontinuous featured surface.

The flow can include detecting a largest feature in the concatenation using a detection algorithm (e.g., OpenCV). The contour detection algorithm can return coordinates of a bounding box that contains the largest feature. The flow can include cropping a region of interest (ROI) based on the bounding box coordinates to form the largest continuous feature at a center of the metasurface design (e.g., the metasurface design in FIG. 12C).

In some examples, the flow can include detecting similar metasurface designs in a batch of metasurface designs after shifting and centering the largest feature at the center using an image similarity module. The image similarity module can identify pairs of metasurface designs that are similar through translation. After detection, relatively similar images are all shifted to have the same representation with the largest feature at the center. It is desirable to train a generator to generate diverse shapes rather than generate the same shapes having different periodicity. For each input metasurface design, the image similarity module can detect a number of feature pixels in each row. If any pair of metasurface designs is associated with an identical list of values, the image similarity module can label those metasurface designs as “similar,” and the flow can output the metasurface design having a higher concentration of feature pixels in the center of the metasurface design.

FIG. 13 illustrates an exemplary flow 1300 of a metasurface design shifting function 1304 according to aspects of this disclosure. The flow 1300 can include providing a first metasurface design 1308 to the to a metasurface design shifting function 1304. The metasurface design shifting function 1304 can shift any discontinuous features in the first metasurface design 1308 to create at least one larger feature. In some examples, the metasurface design shifting function 1304 can shift a number of discontinuous features in the first metasurface design 1308 to create a single largest feature. In some examples, the metasurface design shifting function 1304 can center a largest feature in the first metasurface design 1308.

The metasurface design shifting function 1304 can output a second metasurface design 1312. The second metasurface design 1312 can include shifted features included in the first metasurface design 1308. As illustrated, the first metasurface design 1308 and the second metasurface design 1312 are identical, because the first metasurface design 1308 already included a single centered large feature.

In contrast, the flow 1300 can include providing a third metasurface design 1316 to the metasurface design shifting function 1304. As illustrated, the third metasurface design 1316 can include multiple discontinuous features. The metasurface design shifting function 1304 can output a fourth metasurface design 1320. The fourth metasurface design 1320 can include shifted features included in the third metasurface design 1316. As illustrated, the fourth metasurface design 1320 includes one continuous feature that includes each of the discontinuous features in the third metasurface design 1316.

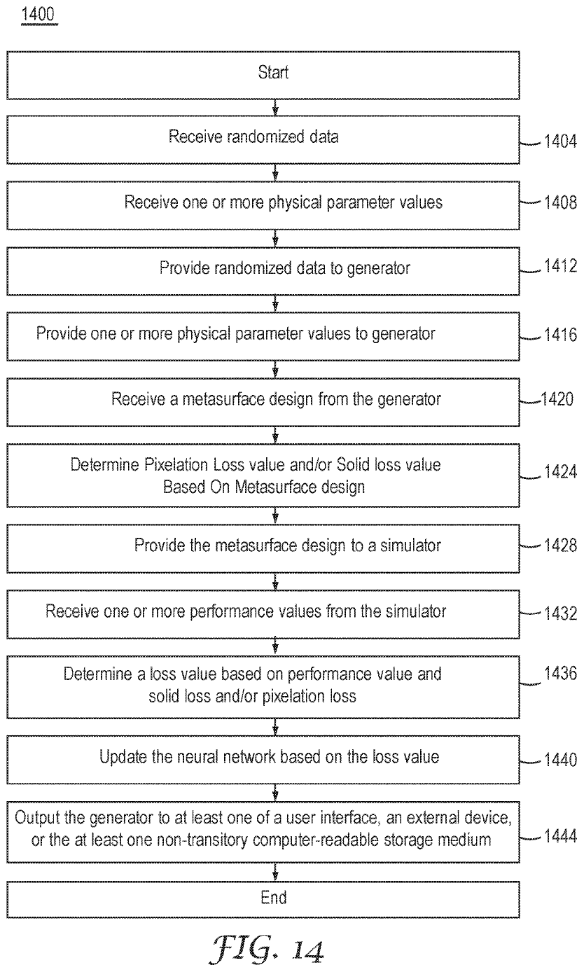

FIG. 14 illustrates an exemplary process 1400 for training a metasurface design generator according to aspects of this disclosure. Specifically, the process 1400 can train a generator to generate metasurface designs that can be manufactured for various metasurface devices. In some examples, the metasurface design can include a metasurface (e.g., the metasurface 300 in FIG. 3). In some examples, the metasurface design can include and/or be associated with a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be of a predetermined thickness and can contain two materials arranged to produce a desired effect (e.g., enhancing transmission efficiency for a certain wavelength and incident angle). In some examples, the generator can be trained to output a metasurface design for a predetermined metasurface device (e.g., a predetermined substrate and superstrate). In some examples, the process 1400 can be implemented in the generator training application 68B and/or the simulator application 68C in FIG. 2.

In some examples, the process 1400 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions. In some examples, the process 1400 can be executed to train a generator (e.g., the generator 412 in FIG. 4). In some examples, the generator can include a machine learning model such as a neural network (e.g., generative network 500 in FIG. 5).

At 1404, the process 1400 can receive randomized data. In some examples, the randomized data can be randomized noise. In some examples, the randomized data can be a random string of values formed into a two-dimensional input matrix. In some examples, the randomized data can be the noise inputs 404 in FIG. 4. In some examples, the process 1400 can receive a set of randomized data (e.g., a set of one hundred or more noise matrices) that can be used to train a generator. The process 1400 can then proceed to 1408.

At 1408, the process 1400 can receive one or more physical parameter values and/or performance parameter values. In some examples, the one or more physical parameter values can be the physical parameter values 408 in FIG. 4. In some examples, the one or more physical parameter values can be referred to as one or more physical parameter values. The one or more physical parameter values can include one or more values and/or ranges that generated metasurface designs may be required to follow (e.g., specifications for a predetermined application). In some examples, the one or more physical parameter values can include a thickness value (e.g., z-axis length), a pitch value for width (e.g., x-axis length), and/or a pitch value for height (e.g., y-axis length). In some examples, the one or more physical parameter values can include a range of values for each of x-axis pitch, y-axis pitch, and/or thickness.

In some examples, the performance parameter values can include one or more of the user-defined metasurface specifications 416 in FIG. 4. The performance parameter values can be selected (e.g., by a user) in order to train the generator to produce metasurface designs having desirable performance qualities. In some examples, the performance parameter values can include a reflection value, a transmission value, and/or an absorption value for one or more wavelengths, angles, and/or orders. In some examples, the performance parameter values can be generated using Equation 2 and/or Equation 3 described above. The process 1400 can then proceed to 1412.

At 1412, the process 1400 can provide the randomized data to the generator. The process 1400 can then proceed to 1416.

At 1416, the process 1400 can provide the physical parameter values to the generator. The process 1400 can then proceed to 1420.

At 1420, the process 1400 can receive a metasurface design from the generator. In some examples, the metasurface design can be the metasurface design 424 in FIG. 4. The metasurface design can include manufacturing data that allows a metasurface to be manufactured based on the metasurface design. Thus, the metasurface design can function as a blueprint for the metasurface. In some examples, the metasurface design can include an x-axis pitch value, a y-axis pitch value, a thickness value, materials information, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design can include a raster surface representation of a metasurface.

In some examples, the process 1400 can shift any discontinuous features in the metasurface design to create at least one larger feature (e.g., using the metasurface design shifting module 1304 in FIG. 13. In some examples, the process 1400 can perform at least a portion of the flow 1300 in FIG. 13. In some examples, the generator can include a metasurface design shifting module (e.g., metasurface design shifting module 1304), and may automatically shift features before outputting the metasurface design. The process 1400 can then proceed to 1424.

At 1424, the process 1400 can determine at least one loss value based on the metasurface design. In some examples, the process 1400 can determine a pixelation loss value and/or a solid loss value based on the metasurface design. The process 1400 can calculate the pixelation loss based on the sum of neighboring pixel absolute differences in the metasurface design. In some examples, the pixelation loss value can penalize the metasurface design if the metasurface design has a large sum of neighboring pixel absolute differences.

The process 1400 can calculate the solid loss value based on a square of a sum of pixel values included in the metasurface design divided by a product of dimensions of the metasurface design. In some examples, the process 1400 can calculate the solid loss value based on Equation 1 described above. In some examples, the process 1400 can determine a manufacturability loss value and/or a cosine loss value. The process 1400 can determine the manufacturability loss value to train the generator to generate metasurfaces that include features that follow predetermined size and gap dimension values. In some examples, the at least one loss value can include the pixelation loss value, the solid loss value, the manufacturability loss value, and/or the cosine loss value. The process 1400 can then proceed to 1428.

At 1428, the process 1400 provide the metasurface design to a simulator. In some examples, the simulator can include the simulator 420 in FIG. 4, the simulator 920 in FIG. 9, the physics-based simulator 1116 in FIG. 11, and/or the machine learning-based simulator 1120 in FIG. 11. In some examples, the process 1400 can provide additional data to the simulator. In some examples, the process 1400 can provide physical parameter values to the simulator. In some examples, the physical parameter values can include pitch values and/or thickness values. In some examples, the process 1400 can scale the physical parameter values before providing the physical parameter values to the simulator. In some examples, the process 1400 can provide a number of Fourier orders to the simulator. In some examples, the simulator can simulate desired optical characteristics (e.g., polarization and/or mode).

In some examples, the simulator can generate one or more performance metric values such as a reflection value, a transmission value, or an absorption value for one or more wavelengths, angles, and/or orders. In some examples, the simulator can include a RCWA simulator such as RETICOLO or S4, and/or a FDTD simulator such as Lumerical or Meep. In some examples, the simulator can generate device gradients based on the metasurface design, the pitch values, and/or the thickness values. The device gradients can include gradients associated with one or more pitch values and/or thickness values. Specifically, the device gradients can be associated with physical parameter values such as the one or more pitch values and/or thickness values because the device gradients reflect overall performance of the metasurface device having certain refractive index values and the physical parameter values, even though the physical parameter values are not differentiable.

In some examples, the process 1400 can provide the metasurface design to a physics-based simulator (e.g., the physics-based simulator 1116 in FIG. 11) and a machine learning-based simulator (e.g., the machine learning-based simulator 1120 in FIG. 11). In some examples, the physics-based simulator can be the simulator 420 in FIG. 4. The physics-based simulator can be configured to generate a simulated property value for a predetermined property such as an efficiency. The machine learning-based physical property estimator can be a neural network that can be trained to generate an estimated property value for the predetermined property. In some examples, the machine learning-based physical property estimator can be trained by the process 1400. In some examples, the machine learning-based physical property estimator can generate an estimated a reflection value, a transmission value, or an absorption value for one or more wavelengths, angles, and/or orders. The wavelengths and/or angles can be associated with source light, and the orders can be associated with output light. The process 1400 can then proceed to 1432.

At 1432, the process 1400 can receive one or more performance values from the simulator. In some examples, the one or more performance values can include a reflection value, a transmission value, and/or an absorption value for one or more wavelengths, angles, and/or orders. In some examples, the one or more performance values can include an estimated reflection value, a transmission value, and/or an absorption value for one or more wavelengths, angles, and/or orders generated by the machine learning-based physical property estimator. The process 1400 can then proceed to 1436.

At 1436, the process 1400 can determine a final loss value based on the at least one loss value and/or the performance value. In some examples, the process 1400 can determine the final loss value based on the pixelation loss value, the solid loss value, the manufacturability loss value, the cosine loss value, and/or the performance value. In some examples, the process 1400 can determine the final loss value based on the pixelation loss value and the performance value. In some examples, the process 1400 can determine the final loss value based on the solid loss value and the performance value. In some examples, the process 1400 can determine the final loss value based on the pixelation loss value, the solid loss value, and the performance value. In some examples, the process 1400 can determine the final loss value based on the performance values and the performance parameter values. In some examples, the final loss value can be calculated based on at least one of Equations 1 and 4-15 described above.

In some examples, the process 1400 can calculate a number of loss values based on an adjoint method to obtain gradients for the metasurface design as described above. The process 1400 can then calculate a base loss value based on the gradients using a base loss function such as a gaussian, sigmoid, or soft plus technique. In some examples, the process 1400 can generate weights for wavelengths, angles, and/or goal efficiencies included the performance parameter values according to a triangle, gaussian, or uniform distribution, and apply the weights, along with any lambda coefficients, to generate a final summation of the loss values. The final summation can then be used as the final loss value. In some examples, the process 1400 can further determine the final loss value based on the loss manufacturability loss value and/or the cosine loss value. The process 1400 can then proceed to 1440.

At 1440, the process 1400 can update the generator based on the final loss value. In some examples, the process 1400 can proceed to 1412 to continue training the generator if a condition has not been met (e.g., a predetermined number of training cycles has not been executed, a predetermined performance value has not been met, etc.). Otherwise, the process 1400 can proceed to 1444.

At 1444, the process 1400 can output the generator to at least one of a user interface, an external device, or at least one non-transitory computer-readable storage medium. The process 1400 can then end.

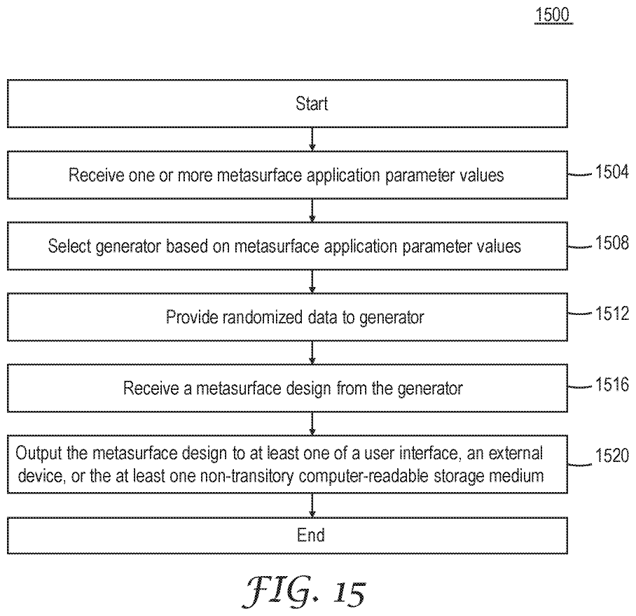

FIG. 15 illustrates an exemplary process 1500 for generating a metasurface design according to aspects of this disclosure. Specifically, the process 1500 can generate metasurface designs that can be manufactured for various metasurface devices. In some examples, the metasurface design can include a metasurface (e.g., the metasurface 300 in FIG. 3). In some examples, the metasurface design can include and/or be associated a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be a predetermined thickness and contains two materials arranged to produce a desired effect (e.g., enhancing transmission efficiency for a certain wavelength and incident angle). In some examples, the generator can be trained to output a metasurface design for a predetermined metasurface device (e.g., a predetermined substrate and superstrate). In some examples, the process 1500 can be implemented in the metasurface design generator application 68A, the generator training application 68B, and/or the simulator application 68C in FIG. 2.

In some examples, the process 1500 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions.

At 1504, the process 1500 can receive one or more metasurface application parameter values. In some examples, the one or more metasurface application parameter values can be selected by a user. In some examples, the one or more metasurface application parameter values can include one or more physical parameter values and/or performance parameter values. In some examples, the one or more physical parameter values can be the physical parameter values 408 in FIG. 4. In some examples, the one or more physical parameter values can be referred to as one or more physical parameter values. The one or more physical parameter values can include one or more values and/or ranges that generated metasurface designs may be required to follow (e.g., specifications for a predetermined application). In some examples, the one or more physical parameter values can include physical parameter values such as thickness values (e.g., z-axis length), pitch values for width (e.g., x-axis length), and/or pitch values for height (e.g., y-axis length). In some examples, the one or more physical parameter values can include a range of values for each of x-axis pitch, y-axis pitch, and thickness.

In some examples, the performance parameter values can include one or more of the user-defined metasurface specifications 416 in FIG. 4. The performance parameter values can be selected (e.g., by the user) in order to train the generator to produce metasurface designs having desirable performance qualities. In some examples, the performance parameter values can include a reflection value, a transmission value, and/or an absorption value for one or more wavelengths, angles, and/or orders. In some examples, the performance parameter values can be generated using Equation 2 and/or Equation 3 described above. The process 1500 can then proceed to 1508.

At 1508, the process 1500 can select a generator based on the one or more metasurface application parameter values. In some examples, the process 1500 can select a trained generator that satisfies each of the one or more metasurface application parameter values. In some examples, the process 1500 can select the generator from a database of pretrained generators. In some examples, the process 1500 can train a generator to generate metasurface designs that satisfy the each of the one or more metasurface application parameter values. In some examples, the process 1500 can execute at least a portion of the process 1400 in FIG. 14 in order to train a generator using the one or more metasurface application parameter values. Once the generator has been selected and/or trained, the process 1500 can proceed to 1512.

At 1512, the process 1500 can provide randomized data to the generator. In some examples, the process 1500 can receive the randomized data from a user and/or database. In some examples, the randomized data can be randomized noise. In some examples, the randomized data can be a random string of values formed into a two-dimensional input matrix. In some examples, the randomized data can be the noise inputs 404 in FIG. 4. The process 1500 can then proceed to 1516.

At 1516, the process 1500 can receive a metasurface design from the generator. In some examples, the metasurface design can be the metasurface design 424 in FIG. 4. The metasurface design can include manufacturing data that allows a metasurface to be manufactured based on the metasurface design. Thus, the metasurface design can be function as a blueprint for the metasurface. In some examples, the metasurface design can include an x-axis pitch value, a y-axis pitch value, a thickness value, materials information, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design can include a raster surface representation of a metasurface.

In some examples, the process 1500 can shift any discontinuous features in the metasurface design to create at least one larger feature (e.g., using the metasurface design shifting module 1304 in FIG. 13). In some examples, the process 1500 can perform at least a portion of the flow 1300 in FIG. 13. In some examples, the generator can include a metasurface design shifting module (e.g., metasurface design shifting module 1304), and may automatically shift features before outputting the metasurface design. The process 1500 can then proceed to 1520.

At 1520, the process 1500 can output the metasurface design to at least one of a user interface, an external device, or the at least one non-transitory computer-readable storage medium. The process 1500 can then end.

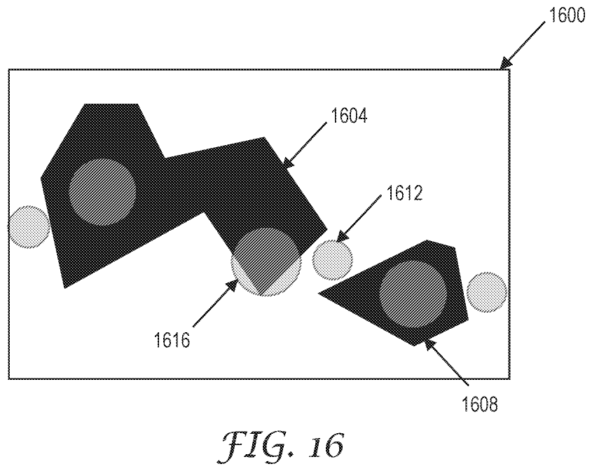

FIG. 16 illustrates exemplary manufacturability constraints overlaid on a metasurface design 1600 according to aspects of this disclosure. Manufacturability constraints can be determined based on capabilities of manufacturing processes. The metasurface design 1600 can include a first feature 1604 and a second feature 1608. In some examples, a first manufacturability constraint 1612 and a second manufacturability constraint 1616. In some examples, the first manufacturability constraint 1612 can be a circle (e.g., a 20 mm circle) that must fit in all areas of the metasurface design. In some examples, the second manufacturability constraint 1616 can be a circle (e.g., a 40 mm circle) that must be contained somewhere in each continuous metasurface feature.

Referring broadly to FIGS. 16-24, approaches for generating manufacturable metasurface devices are presented. One approach to generate manufacturable metasurface designs is to incorporate losses that penalize surfaces generated during training that are not manufacturable. In this way, a generator is encouraged to generate surfaces that satisfy certain manufacturability requirements such as feature size and/or gap size.

In testing, certain loss functions have been found to be effective at changing characteristics of generated surfaces, which are represented as 2D images. One example is total variation, which is the sum of the absolute differences of each pixel against its neighbors below and to the right. Minimizing total variation has the effect of penalizing edges, which in turn may discourage small features or features with hard edges. Since other loss terms and architecture elements encourage binarized values, total variation loss may discourage small features that are difficult to manufacture.

An aspect of the loss function-based techniques described above is that each loss function needs to be differentiable. Many measurements of metasurface designs that determine whether the metasurface designs are manufacturable may be straightforward to implement using traditional image processing techniques but difficult to implement as a differentiable loss. One example is measuring the area of each connected component in the binarized surface. While ideally, connected components with small areas should be penalized, implementing such a penalty as a differentiable loss with a meaningful gradient is a potential challenge.

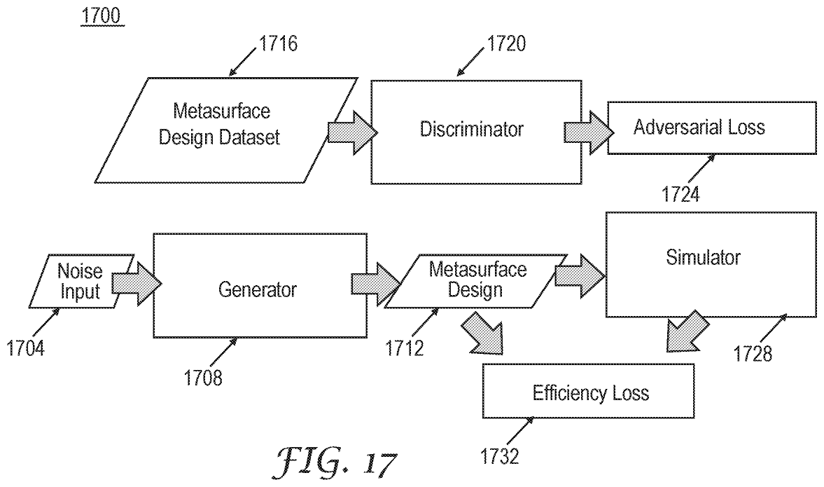

Another approach to encouraging manufacturability that retains the existing generative network and surface representation is to add a discriminator network to form a generative adversarial network (GAN) as shown in FIG. 17. Using a GAN, manufacturable surfaces can function as a ground truth for the quality of manufacturability in generated metasurface designs. In addition to an adjoint-based loss, a discriminator network and an adversarial loss can penalize generated surfaces that do not resemble the manufacturable ground truth. An advantage of using a GAN is that the process of sampling manufacturable metasurface designs does not need to be differentiable and thus could be parameterized for various applications.

FIG. 17 illustrates an exemplary flow 1700 for training a generative adversarial network (GAN) to generate metasurface designs according to aspects of this disclosure. In some examples, the flow 1700 can include providing noise input 1704 to a generator 1708. The generator 1708 can be trained to output a metasurface design 1712. The noise input 1704 can be the noise input 904 in FIG. 9. The generator 1708 can be the generator 912 in FIG. 9. The metasurface design 1712 can be the metasurface design 924 in FIG. 9.

The metasurface design can be provided to a discriminator 1720 along with a metasurface design included in a metasurface design dataset 1716. The discriminator 1720 can be a machine learning model such as a neural network. In some examples, the discriminator 1720 can be the same model as the generator 1708. The discriminator 1720 can be configured to guess whether the metasurface design 1712 is manufacturable based on the metasurface design dataset 1716. The discriminator 1720 can output an adversarial loss value 1724 based on how manufacturable the metasurface design 1712 is. The metasurface design 1712 can be provided to a simulator 1728. The simulator 1728 can be the simulator 920 in FIG. 9. The simulator 1728 can generate an efficiency loss value 1732 based one or more performance parameter values as described above. The flow 1700 can then update the generator 1708 and/or the discriminator 1720 based on the adversarial loss value 1724 and/or the efficiency loss value 1732. In this way, the flow 1700 can train the generator 1708 to generate manufacturable metasurface designs.

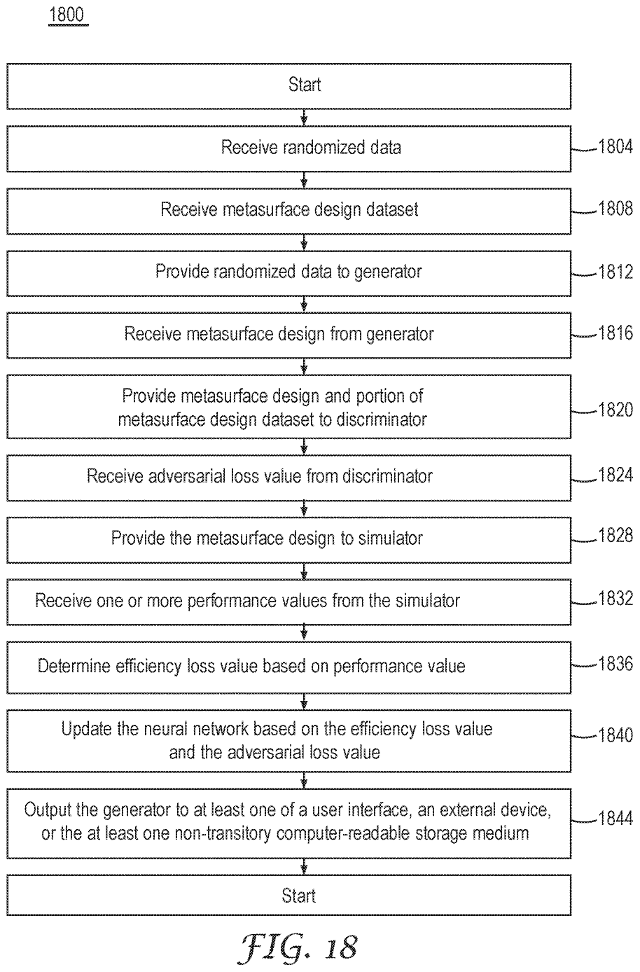

FIG. 18 illustrates a process 1800 for training a GAN according to aspects of this disclosure. Specifically, the process 1800 can train a generator to generate manufacturable metasurface designs using a discriminator during training. In some examples, the metasurface design can include a metasurface (e.g., the metasurface 300 in FIG. 3). In some examples, the metasurface design can include and/or be associated a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be a predetermined thickness and contains two materials arranged to produce a desired effect (e.g., enhancing transmission efficiency for a certain wavelength and incident angle). In some examples, the generator can be trained to output a metasurface design for a predetermined metasurface device (e.g., a predetermined substrate and superstrate). In some examples, the process 1800 can be implemented in the generator training application 68B and/or the simulator application 68C in FIG. 2.

In some examples, the process 1800 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions. In some examples, the process 1800 can be executed to train a generator (e.g., the generator 1708 in FIG. 17). In some examples, the generator and the discriminator can include a machine learning model such as a neural network (e.g., generative network 500 in FIG. 5).

At 1804, the process 1800 can receive randomized data. In some examples, the randomized data can be randomized noise. In some examples, the randomized data can be a random string of values formed into a two-dimensional input matrix. In some examples, the randomized data can be the noise inputs 1704 in FIG. 17. In some examples, the process 1800 can receive a set of randomized data (e.g., a set of one hundred or more noise matrices) that can be used to train a generator. The process 1800 can then proceed to 1808.

At 1808, the process 1800 can receive a metasurface design dataset. The metasurface design dataset can include a set of metasurface designs representative of manufacturable metasurfaces. The process 1800 can then proceed to 1812.

At 1812, the process 1800 can provide the randomized data to the generator. The process 1800 can then proceed to 1816.

At 1816, the process 1800 can receive a metasurface design from the generator. In some examples, the metasurface design can be the metasurface design 1712 in FIG. 17. The metasurface design can include manufacturing data that allows a metasurface to be manufactured based on the metasurface design. Thus, the metasurface design can be function as a blueprint for the metasurface. In some examples, the metasurface design can include an x-axis pitch value, a y-axis pitch value, a thickness value, materials information, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design can include a raster surface representation of a metasurface.

In some examples, the process 1800 can shift any discontinuous features in the metasurface design to create at least one larger feature (e.g., using the metasurface design shifting module 1304 in FIG. 13. In some examples, the process 1800 can perform at least a portion of the flow 1300 in FIG. 13. In some examples, the generator can include a metasurface design shifting module (e.g., metasurface design shifting module 1304), and may automatically shift features before outputting the metasurface design. The process 1800 can then proceed to 1820.

At 1820, the process 1800 can provide the metasurface design and a portion of the metasurface design dataset to the discriminator. The portion of the metasurface design dataset can include a metasurface design associated with a manufacturable metasurface. The process 1800 can then proceed to 1824.

At 1824, the process 1800 can receive an adversarial loss value from the discriminator. The discriminator can generate the adversarial loss value based on the metasurface design and the portion of metasurface design dataset. The discriminator can generate the adversarial loss value based on how manufacturable the metasurface design. The process 1800 can then proceed to 1828.

At 1828, the process 1800 can provide the metasurface design to a simulator. In some examples, the simulator can include the simulator 420 in FIG. 4, the simulator 920 in FIG. 9, the physics-based simulator 1116 in FIG. 11, the machine learning-based simulator 1120 in FIG. 11, and/or the simulator 1728 in FIG. 17. In some examples, the process 1800 can provide additional data to the simulator. In some examples, the process 1800 can provide physical parameter values to the simulator. In some examples, the physical parameter values can include pitch values and/or thickness values. In some examples, the process 1800 can scale the physical parameter values before providing the physical parameter values to the simulator. In some examples, the process 1800 can provide a number of Fourier orders to the simulator. In some examples, the simulator can simulate desired optical characteristics (e.g., polarization and/or mode).

In some examples, the simulator can generate one or more performance metric values such as a reflection value, a transmission value, or an absorption value for one or more wavelengths, angles, and/or orders. In some examples, the simulator can include a RCWA simulator such as RETICOLO or S4, and/or a FDTD simulator such as Lumerical or Meep. In some examples, the simulator can generate device gradients based on the metasurface design. The device gradients can include gradients associated with one or more pitch values and/or thickness values. Specifically, the device gradients can be associated with physical parameter values such as the one or more pitch values and/or thickness values because the device gradients reflect overall performance of the metasurface device having certain refractive index values and the physical parameter values, even though the physical parameter values are not differentiable. The process 1800 can then proceed to 1832.

At 1832, the process 1800 can receive one or more performance values from the simulator. In some examples, the one or more performance values can include a reflection value, a transmission value, and/or an absorption value for one or more wavelengths, angles, and/or orders. The process 1800 can then proceed to 1836.

At 1836, the process 1800 can determine a loss value based on the performance value. In some examples, the process 1800 can determine the loss value based on the performance values and a set of performance parameter values. In some examples, the process 1800 can receive one or more performance parameter values (e.g., from a user) that are indicative of performance targets for the metasurface design. In some examples, the loss can be calculated based on at least one of Equations 1 and 4-15 described above.

In some examples, the process 1800 can calculate a number of loss values based on an adjoint method to obtain gradients for the metasurface design as described above. The process 1800 can then calculate a base loss value based on the gradients using a base loss function such as a gaussian, sigmoid, or soft plus technique. In some examples, the process 1800 can generate weights for wavelengths, angles, and/or goal efficiencies included the performance parameter values according to a triangle, gaussian, or uniform distribution, and apply the weights, along with any lambda coefficients, to generate a final summation of the loss values. The final summation can then be used as the loss value. The process 1800 can then proceed to 1840.

At 1840, the process 1800 can update the generator based on the efficiency loss value the adversarial loss value. In some examples, the process 1800 can proceed to 1812 to continue training the generator if a condition has not been met (e.g., a predetermined number of training cycles has not been executed, a predetermined performance value has not been met, etc.). Otherwise, the process 1800 can proceed to 1844.

At 1844, the process 1800 can output the generator to at least one of a user interface, an external device, or the at least one non-transitory computer-readable storage medium. The process 1800 can then end.

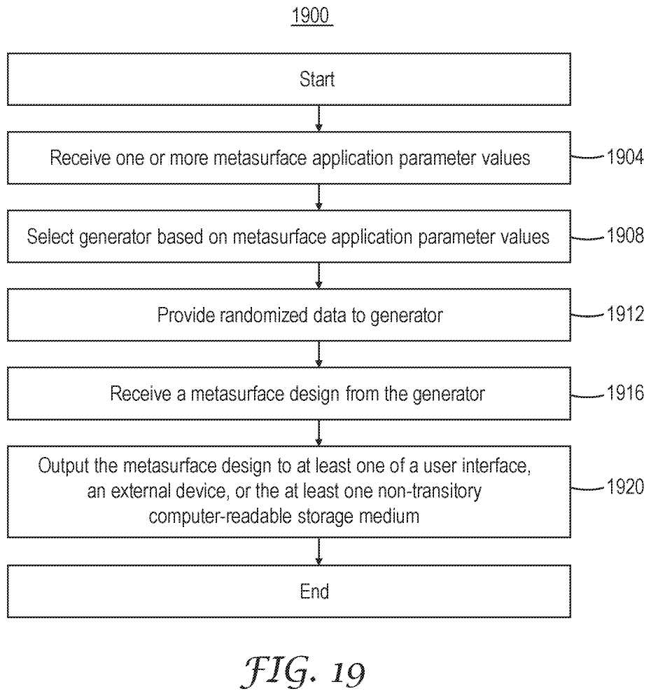

FIG. 19 illustrates an exemplary process 1900 for generating a metasurface design using a GAN according to aspects of this disclosure. Specifically, the process 1900 can generate metasurface designs that can be manufactured for various metasurface devices using the GAN. In some examples, the metasurface design can include a metasurface (e.g., the metasurface 300 in FIG. 3). In some examples, the metasurface design can include and/or be associated a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be a predetermined thickness and contains two materials arranged to produce a desired effect (e.g., enhancing transmission efficiency for a certain wavelength and incident angle). In some examples, the generator can be trained to output a metasurface design for a predetermined metasurface device (e.g., a predetermined substrate and superstrate). In some examples, the process 1900 can be implemented in the metasurface design generator application 68A, the generator training application 68B, and/or the simulator application 68C in FIG. 2.

In some examples, the process 1900 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions.

At 1904, the process 1900 can receive one or more metasurface application parameter values. In some examples, the one or more metasurface application parameter values can be selected by a user. In some examples, the one or more metasurface application parameter values can include one or more physical parameter values and/or performance parameter values. In some examples, the one or more physical parameter values can be the physical parameter values 408 in FIG. 4. In some examples, the one or more physical parameter values can be referred to as one or more physical parameter values. The one or more physical parameter values can include one or more values and/or ranges that generated metasurface designs may be required to follow (e.g., specifications for a predetermined application). In some examples, the one or more physical parameter values can include physical parameter values such as thickness values (e.g., z-axis length), pitch values for width (e.g., x-axis length), and/or pitch values for height (e.g., y-axis length). In some examples, the one or more physical parameter values can include a range of values for each of x-axis pitch, y-axis pitch, and thickness.

In some examples, the performance parameter values can include one or more of the user-defined metasurface specifications 416 in FIG. 4. The performance parameter values can be selected (e.g., by the user) in order to train the generator to produce metasurface designs having desirable performance qualities. In some examples, the performance parameter values can include a reflection value, a transmission value, and/or an absorption value for one or more wavelengths, angles, and/or orders. In some examples, the performance parameter values can be generated using Equation 2 and/or Equation 3 described above. The process 1900 can then proceed to 1908.

At 1908, the process 1900 can select a generator based on the one or more metasurface application parameter values. In some examples, the process 1900 can select a trained generator that satisfies each of the one or more metasurface application parameter values. In some examples, the process 1900 can select the generator from a database of generators previously trained using a discriminator in a GAN. In some examples, the process 1900 can train a generator to generate metasurface designs that satisfy the each of the one or more metasurface application parameter values. In some examples, the process 1900 can execute at least a portion of the process 1800 in FIG. 18 in order to train a generator using the one or more metasurface application parameter values. Once the generator has been selected and/or trained, the process 1900 can proceed to 1912.

At 1912, the process 1900 can provide randomized data to the generator. In some examples, the process 1900 can receive the randomized data from a user and/or database. In some examples, the randomized data can be randomized noise. In some examples, the randomized data can be a random string of values formed into a two-dimensional input matrix. In some examples, the randomized data can be the noise inputs 1704 in FIG. 17. The process 1900 can then proceed to 1916.

At 1916, the process 1900 can receive a metasurface design from the generator. In some examples, the metasurface design can be the metasurface design 1712 in FIG. 17. The metasurface design can include manufacturing data that allows a metasurface to be manufactured based on the metasurface design. Thus, the metasurface design can be function as a blueprint for the metasurface. In some examples, the metasurface design can include an x-axis pitch value, a y-axis pitch value, a thickness value, materials information, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design can include a raster surface representation of a metasurface.

In some examples, the process 1900 can shift any discontinuous features in the metasurface design to create at least one larger feature (e.g., using the metasurface design shifting module 1304 in FIG. 13). In some examples, the process 1900 can perform at least a portion of the flow 1300 in FIG. 13. In some examples, the generator can include a metasurface design shifting module (e.g., metasurface design shifting module 1304), and may automatically shift features before outputting the metasurface design. The process 1900 can then proceed to 1920.

At 1920, the process 1900 can output the metasurface design to at least one of a user interface, an external device, or the at least one non-transitory computer-readable storage medium. The process 1900 can then end.

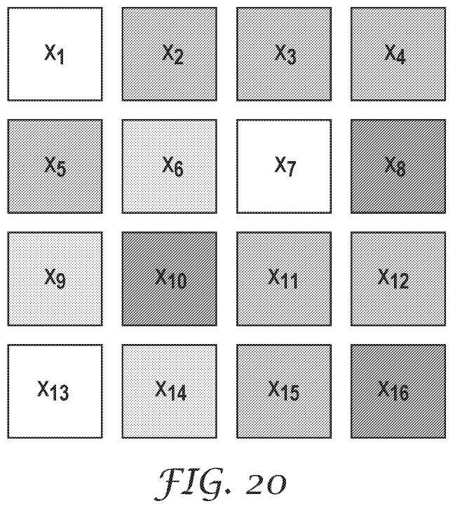

FIG. 20 illustrates an exemplary raster surface representation of a metasurface design according to aspects of this disclosure. The raster surface representation can include a number of variables. Each variable included in the raster surface representation can represent an index of refraction of a pixel in a fixed location. In some simulators, such as RETICOLO, a metasurface design is represented not as a raster image, but as a set of features. Each of the features can include an index of refraction, a height, a width, and a shape. The shape can range from rectangular to oval shaped. As described above, generators can be trained to generate metasurface designs including a raster surface representation of a metasurface. Before simulation, the raster surface representation needs to be converted to a set of features. In some examples, a process can convert the raster surface representation to a set of features using a function that constructs one rectangular feature for each pixel in the raster surface representation, with an index of refraction based on the value of the pixel.

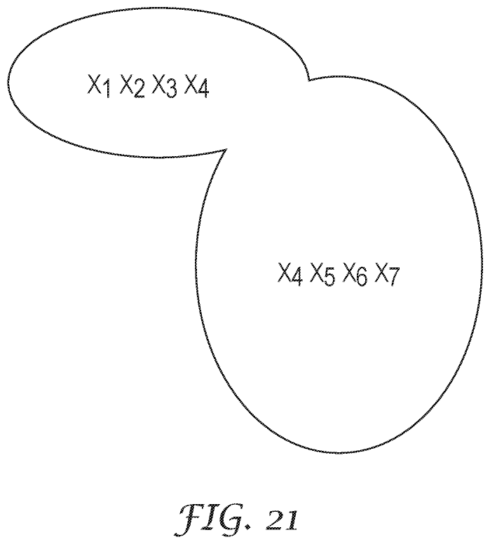

FIG. 21 illustrates an exemplary non-raster surface representation of a metasurface design according to aspects of this disclosure. In some examples, a non-raster representation of features can directly describe the size and positions of individual features. The non-raster representation of features can include, for each, feature, a height value, a width value, an x position, and a y position. The adjoint method cannot calculate a gradient based on the non-raster representation, so finite differences can be calculated to approximate the gradient instead. The finite differences require 1+N simulations to estimate the gradient, where N is the number of degrees of freedom of the representation. The adjoint method requires 1+M simulations, where M is the number of orders that gradients are required for.

For small numbers of orders, it would seem that that the adjoint method would be more efficient than the finite differences method. However, simulation time is linear in the number of features. Depending on what kind of surface geometry is desired in a metasurface design, it may be possible to describe using a non-raster representation with far fewer features than a raster representation, thus narrowing the performance gap. The non-raster representation can describe the size and positions of individual features can incorporate manufacturability constraints. In some examples, metasurface generator output in the (−1, 1) range could be scaled to minimum and maximum feature sizes and positions before providing the metasurface design to a simulator.

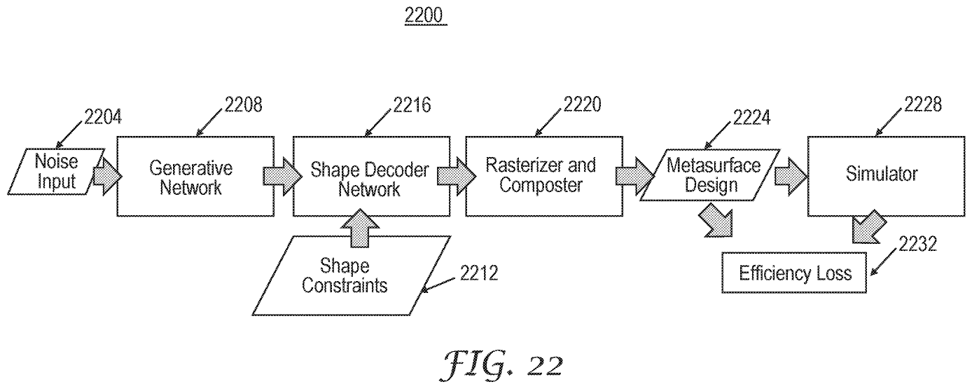

FIG. 22 illustrates an exemplary flow 2200 for training a generator to generate metasurface designs using a rasterization technique according to aspects of this disclosure. The flow 2200 can utilize the adjoint method and a generator that produces non-raster representations of a metasurface. The flow 2200 can utilize a shape decoder network 2216 to convert a more abstract representation produced by the network to a raster for the simulation.

The flow 2200 can include providing noise 2204 input to a generative network 2208. The noise input 2204 can be the noise input 1704 in FIG. 17. The generative network 2208 can be a machine learning model such as a neural network (e.g., a recurrent neural network). The generative network 2208 can be trained to output a metasurface design having a non-raster representation. The non-raster representation can include a set of codes. The metasurface design can be provided to a shape decoder network 2216 along with shape constraints 2212. The shape decoder network 2216 can convert each code included in the metasurface design to a vector path based on the shape constraints 2212. The flow 2200 can provide the vector path to a rasterizer and compositor 2220 that generates a final metasurface design 2224. The flow can provide the final metasurface design 2224 to a simulator 2228 to generate an efficiency loss, which can be used to update the generative network 2208.

The flow 2200 can use the shape decoder 2216 and the differentiable rasterizer and compositor 2220 to convert the output of the generative network 2208 to a raster before simulation. The shape decoder 2216 can include non-learnable parameters which can be adapted to place limits on the size or complexity of predicted paths. The non-learnable parameters can allow control over feature size described in the finite differences approach above, while allowing the generative network 2208 to predict and optimize features that are more complex than the rectangle and oval simulator primitives.

Using a non-raster representation may offer additional opportunities for loss functions to encourage manufacturability. Even if the representation itself allows for some non-manufacturable surfaces, implementing loss functions to encourage manufacturability may be more straightforward. For example, a loss penalizing small distances between each feature and its neighbors can be implemented in the approach using simulator primitives and finite differences. By using a differentiable rasterization technique such as the flow 2200, a loss which penalizes small, connected components can be implemented given the structure of the differentiable rasterizer and compositor.

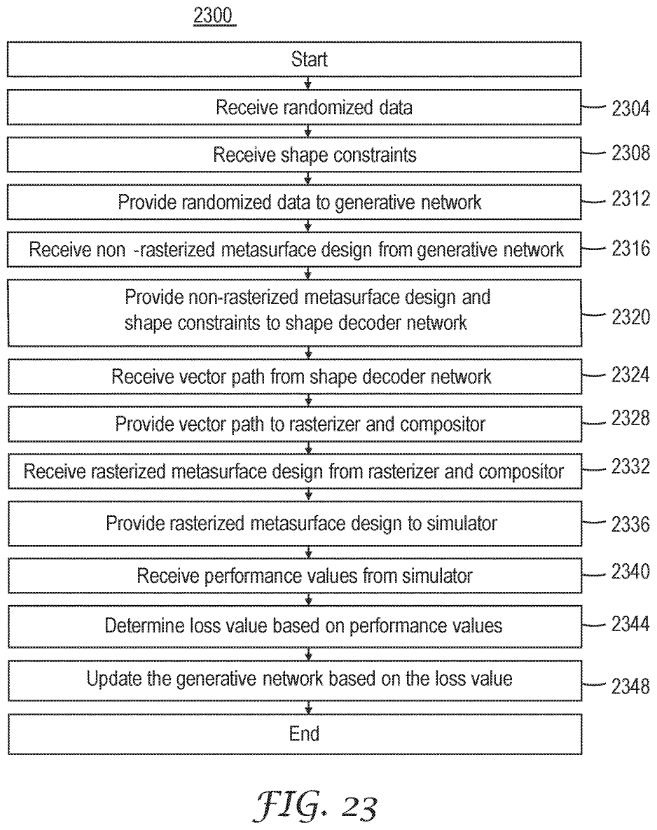

FIG. 23 illustrates an exemplary process 2300 for training a generator to generate metasurface designs using a rasterization technique according to aspects of this disclosure. Specifically, the process 2300 can train a generator to generate manufacturable metasurface designs using a rasterizer and compositor during training. In some examples, the metasurface design can include a metasurface (e.g., the metasurface 300 in FIG. 3). In some examples, the metasurface design can include and/or be associated a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be a predetermined thickness and contains two materials arranged to produce a desired effect (e.g., enhancing transmission efficiency for a certain wavelength and incident angle). In some examples, the generator can be trained to output a metasurface design for a predetermined metasurface device (e.g., a predetermined substrate and superstrate). In some examples, the generator can include the generative network 2208, the shape decoder network 2216, and the rasterizer and compositor 2220 in FIG. 22. In some examples, the process 2300 can be implemented in the generator training application 68B and/or the simulator application 68C in FIG. 2.

In some examples, the process 2300 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions.

At 2304, the process 2300 can receive randomized data. In some examples, the randomized data can be randomized noise. In some examples, the randomized data can be a random string of values formed into a two-dimensional input matrix. In some examples, the randomized data can be the noise inputs 2204 in FIG. 22. In some examples, the process 2300 can receive a set of randomized data (e.g., a set of one hundred or more noise matrices) that can be used to train a generative network. The process 2300 can then proceed to 2308.

At 2308, the process 2300 can receive shape constraints. The shape constraints can include one or more constraints that may encourage generation of manufacturable metasurface designs. The process 2300 can then proceed to 2312.

At 2312, the process 2300 can provide the randomized data to a generative network. The process 2300 can then proceed to 2316.

At 2316, the process 2300 can receive a non-rasterized metasurface design from the generative network. The non-raster representation can include a set of codes. The process 2300 can then proceed to 2320.

At 2320, the process 2300 can provide the non-rasterized metasurface design and the shape constraints to a shape decoder network. The shape decoder network can convert each code included in the metasurface design to a vector path based on the shape constraints 2212. The process 2300 can then proceed to 2324.

At 2324, the process 2300 can receive a vector path from the shape decoder network. The process 2300 can then proceed to 2328.

At 2328, the process 2300 can provide the vector path to the rasterizer and compositor. The process 2300 can then proceed to 2332.

At 2332, the process 2300 receive a rasterized metasurface design from the rasterizer and compositor. The process 2300 can then proceed to 2336.

At 2336, the process 2300 can provide the rasterized metasurface design to a simulator. In some examples, the simulator can include the simulator 420 in FIG. 4, the simulator 920 in FIG. 9, the physics-based simulator 1116 in FIG. 11, the machine learning-based simulator 1120 in FIG. 11, the simulator 1728 in FIG. 17, and/or the simulator 2228 in FIG. 22. In some examples, the process 2300 can provide additional data to the simulator. In some examples, the process 2300 can provide physical parameter values to the simulator. In some examples, the physical parameter values can include pitch values and/or thickness values. In some examples, the process 2300 can scale the physical parameter values before providing the physical parameter values to the simulator. In some examples, the process 2300 can provide a number of Fourier orders to the simulator. In some examples, the simulator can simulate desired optical characteristics (e.g., polarization and/or mode).

In some examples, the simulator can generate one or more performance metric values such as a reflection value, a transmission value, or an absorption value for one or more wavelengths, angles, and/or orders. In some examples, the simulator can include a RCWA simulator such as RETICOLO or S4, and/or a FDTD simulator such as Lumerical or Meep. In some examples, the simulator can generate device gradients based on the rasterized metasurface design, the pitch values, and/or the thickness values. The device gradients can include gradients associated with one or more pitch values and/or thickness values. Specifically, the device gradients can be associated with physical parameter values such as the one or more pitch values and/or thickness values because the device gradients reflect overall performance of the metasurface device having certain refractive index values and the physical parameter values, even though the physical parameter values are not differentiable. The process 2300 can then proceed to 2340.

At 2340, the process 2300 can receive one or more performance values from the simulator. In some examples, the one or more performance values can include a reflection value, a transmission value, and/or an absorption value for one or more wavelengths, angles, and/or orders. The process 2300 can then proceed to 2344.

At 2344, the process 2300 can determine a loss value based on the performance value. In some examples, the process 2300 can determine the loss value based on the performance values and a set of performance parameter values. In some examples, the process 2300 can receive one or more performance parameter values (e.g., from a user) that are indicative of performance targets for the rasterized metasurface design. In some examples, the loss can be calculated based on at least one of Equations 1 and 4-15 described above.

In some examples, the process 2300 can calculate a number of loss values based on an adjoint method to obtain gradients for the rasterized metasurface design as described above. The process 2300 can then calculate a base loss value based on the gradients using a base loss function such as a gaussian, sigmoid, or soft plus technique. In some examples, the process 2300 can generate weights for wavelengths, angles, and/or goal efficiencies included the performance parameter values according to a triangle, gaussian, or uniform distribution, and apply the weights, along with any lambda coefficients, to generate a final summation of the loss values. The final summation can then be used as the loss value. The process 2300 can then proceed to 2348.

At 2348, the process 2300 can update the generative network based on the efficiency loss value the adversarial loss value. In some examples, the process 2300 can proceed to 2312 to continue training the generative network if a condition has not been met (e.g., a predetermined number of training cycles has not been executed, a predetermined performance value has not been met, etc.). Otherwise, the process 2300 can proceed to 2352.

At 2352, the process 2300 can output the generator to at least one of a user interface, an external device, or the at least one non-transitory computer-readable storage medium. The generator can include the generative network, the shape decoder network, and the rasterizer and compositor. The process 2300 can then end.

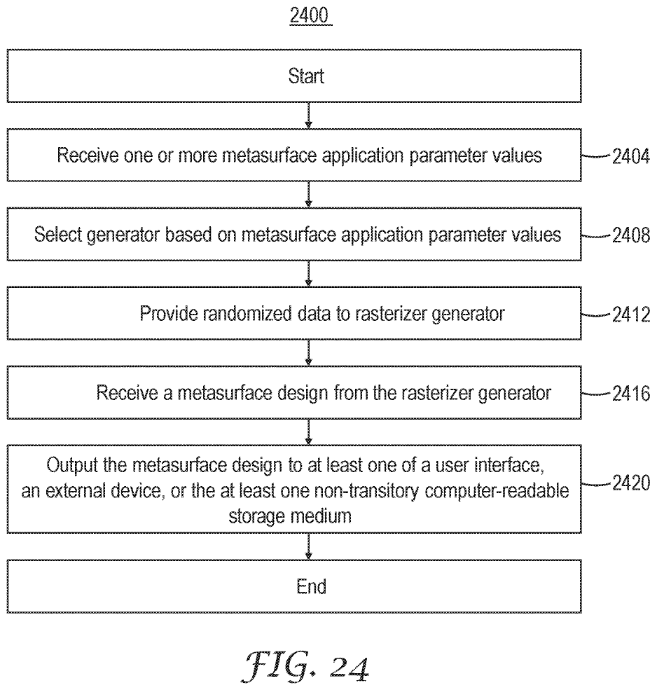

FIG. 24 illustrates an exemplary process for generating metasurface designs using a rasterization technique according to aspects of this disclosure. In some examples, the metasurface design can include a metasurface (e.g., the metasurface 300 in FIG. 3). In some examples, the metasurface design can include and/or be associated a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be a predetermined thickness and contains two materials arranged to produce a desired effect (e.g., enhancing transmission efficiency for a certain wavelength and incident angle). In some examples, the generator can be trained to output a metasurface design for a predetermined metasurface device (e.g., a predetermined substrate and superstrate). In some examples, the process 2400 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions.

At 2404, the process 2400 can receive one or more metasurface application parameter values. In some examples, the one or more metasurface application parameter values can be selected by a user. In some examples, the one or more metasurface application parameter values can include one or more physical parameter values, shape constraints, and/or performance parameter values. In some examples, the one or more physical parameter values can be the physical parameter values 408 in FIG. 4. In some examples, the one or more physical parameter values can be referred to as one or more physical parameter values. The one or more physical parameter values can include one or more values and/or ranges that generated metasurface designs may be required to follow (e.g., specifications for a predetermined application). In some examples, the one or more physical parameter values can include physical parameter values such as thickness values (e.g., z-axis length), pitch values for width (e.g., x-axis length), and/or pitch values for height (e.g., y-axis length). In some examples, the one or more physical parameter values can include a range of values for each of x-axis pitch, y-axis pitch, and thickness.

In some examples, the performance parameter values can include one or more of the user-defined metasurface specifications 416 in FIG. 4. The performance parameter values can be selected (e.g., by the user) in order to train the generator to produce metasurface designs having desirable performance qualities. In some examples, the performance parameter values can include a reflection value, a transmission value, and/or an absorption value for one or more wavelengths, angles, and/or orders. In some examples, the performance parameter values can be generated using Equation 2 and/or Equation 3 described above. The process 2400 can then proceed to 2408.

At 2408, the process 2400 can select a generator based on the one or more metasurface application parameter values. In some examples, the process 2400 can select a trained generator that satisfies each of the one or more metasurface application parameter values. In some examples, the process 2400 can select the generator from a database of generators that include generative networks configured to generative non-rasterized metasurface designs. In some examples, the process 2400 can train a generator to generate metasurface designs that satisfy the each of the one or more metasurface application parameter values. In some examples, the process 2400 can execute at least a portion of the process 2300 in FIG. 23 in order to train a generator using the one or more metasurface application parameter values. Once the generator has been selected and/or trained, the process 2400 can proceed to 2412.

At 2412, the process 2400 can provide randomized data to the generator. In some examples, the process 2400 can receive the randomized data from a user and/or database. In some examples, the randomized data can be randomized noise. In some examples, the randomized data can be a random string of values formed into a two-dimensional input matrix. In some examples, the randomized data can be the noise inputs 2204 in FIG. 22. The process 2400 can then proceed to 2416.

At 2416, the process 2400 can receive a metasurface design from the generator. In some examples, the metasurface design can be the final metasurface design 2224 in FIG. 22. The metasurface design can include manufacturing data that allows a metasurface to be manufactured based on the metasurface design. Thus, the metasurface design can be function as a blueprint for the metasurface. In some examples, the metasurface design can include an x-axis pitch value, a y-axis pitch value, a thickness value, materials information, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design can include a raster surface representation of a metasurface.

In some examples, the process 2400 can shift any discontinuous features in the metasurface design to create at least one larger feature (e.g., using the metasurface design shifting module 1304 in FIG. 13. In some examples, the process 2400 can perform at least a portion of the flow 1300 in FIG. 13. In some examples, the generator can include a metasurface design shifting module (e.g., metasurface design shifting module 1304), and may automatically shift features before outputting the metasurface design. The process 2400 can then proceed to 2420.

At 2420, the process 2400 can output the metasurface design to at least one of a user interface, an external device, or the at least one non-transitory computer-readable storage medium. The process 2400 can then end.

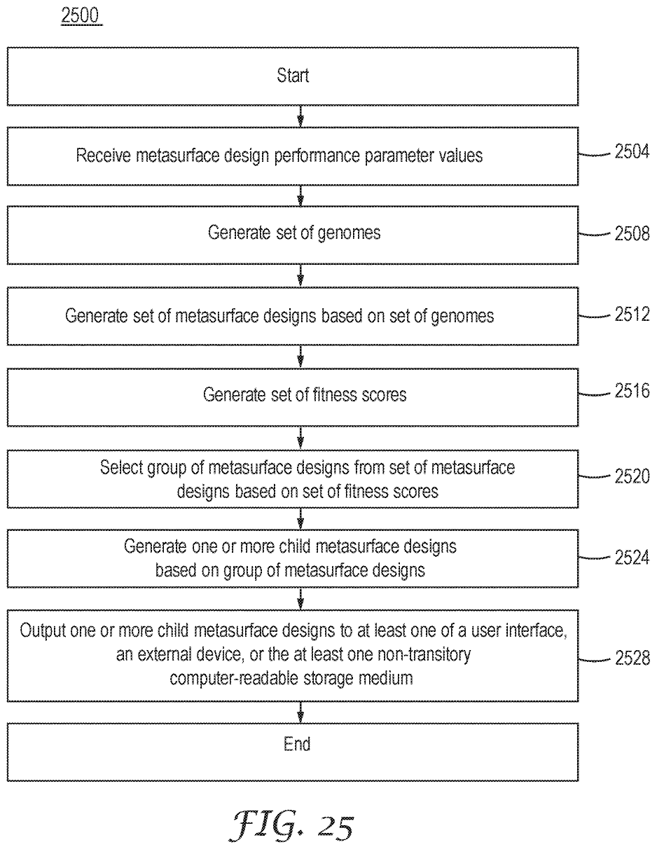

FIG. 25 illustrates an exemplary process 2500 for generating metasurface designs using a genetic algorithm technique according to aspects of this disclosure. In some examples, the metasurface design can include a metasurface (e.g., the metasurface 300 in FIG. 3). In some examples, the metasurface design can include and/or be associated a metasurface device and/or portions of the metasurface device (e.g., the metasurface device 304 in FIG. 3). In some examples, the metasurface design can include a superstrate (e.g., the superstrate 308 in FIG. 3) and a substrate (e.g., the substrate 312 in FIG. 3). In some examples, the metasurface device and/or portions of the metasurface device can be predetermined. In some examples, the metasurface can be exposed to air on one or more sides, meaning the superstrate and/or the substrate can be air. In some examples, the superstrate and/or the substrate can include one or more solid materials such as a polymer (e.g., polyethylene terephthalate and/or polyvinyl butyral) and/or silica glass. In some examples, the superstrate and/or the substrate can be a uniform material having a predetermined thickness. In some examples, the superstrate and/or the substrate can include multiple layers of materials each having a predetermined thickness. In some examples, the superstrate and/or the substrate can be the same. The metasurface can be a predetermined thickness and contains two materials arranged to produce a desired effect (e.g., enhancing transmission efficiency for a certain wavelength and incident angle). In some examples, the process 2500 can be implemented in the metasurface design generator application 68A in FIG. 2. In some examples, the process 2500 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions.

At 2504, the process 2500 can receive metasurface design performance parameter values. In some examples, the metasurface design performance parameter values can include one or more of the user-defined metasurface specifications 416 in FIG. 4. The performance parameter values can be selected (e.g., by the user) in order to train the generator to produce metasurface designs having desirable performance qualities. In some examples, the performance parameter values can include a reflection value, a transmission value, and/or an absorption value for one or more wavelengths, angles, and/or orders. In some examples, the performance parameter values can be generated using Equation 2 and/or Equation 3 described above. The process 2500 can then proceed to 2508.

At 2508, the process 2500 can generate a set of genomes. In some examples, each genome included in the set of genomes can include a one-dimensional array. Each element in the one-dimensional array may be referred to as a gene. In some examples, each genome included in the set of genomes can be generated randomly. The process 2500 can then proceed to 2512.

At 2512, the process 2500 can generate a set of metasurface designs based on the set of genomes. In some examples, the process 2500 can generate the set of metasurface designs by, for each genome included in the set of genomes, generating a two-dimensional matrix. The process 2500 can then upscale each two-dimensional matrix to generate an associated metasurface design included in the set of metasurface designs.

Each metasurface design can include manufacturing data that allows a metasurface to be manufactured based on the metasurface design. Thus, the metasurface design can be function as a blueprint for the metasurface. In some examples, the metasurface design can include an x-axis pitch value, a y-axis pitch value, a thickness value, materials information, and a mapping of one or more features. The mapping of one or more features can include location data (e.g., x and y coordinates) of one or more features in the metasurface. Each feature can be a continuous portion of a given material. For example, a metasurface including two materials may have ten features, with four features formed from a first material and six features formed from a second material. In some examples, the metasurface design can include a raster surface representation of a metasurface.

In some examples, the process 2500 can shift any discontinuous features in the metasurface design to create at least one larger feature (e.g., using the metasurface design shifting module 1304 in FIG. 13. In some examples, the process 2500 can perform at least a portion of the flow 1300 in FIG. 13. In some examples, the generator can include a metasurface design shifting module (e.g., metasurface design shifting module 1304), and may automatically shift features before outputting the metasurface design. The process 2500 can then proceed to 2516.

At 2516, the process 2500 can generate a set of fitness scores. Each fitness score included in the set of fitness scores can be associated with a metasurface design included in the set of metasurface designs. In some examples, the process 2500 can generate the set of fitness scores by providing each of the metasurface designs to a simulator configured to generate one or more performance metric values for each metasurface design. The one or more performance metric values can include a reflection value, a transmission value, and/or an absorption value for one or more wavelengths, angles, and/or orders. The process 2500 can then receive the performance metric values from the simulator. The process 2500 can generate the fitness scores based on the performance metric values and the metasurface design performance parameter values. In some examples, the process 2500 can calculate each fitness score by summing the performance metric values for each of the metasurface design performance parameter values. The process 2500 can then proceed to 2520.

At 2520, the process 2500 can select a group of metasurface designs from the set of metasurface designs based on the set of fitness scores. In some examples, the process 2500 can select a top-scoring portion of the group of metasurface designs. For examples, the process 2500 can select a group of the metasurface designs having fitness scores in the top ten percent of all metasurface designs. The process 2500 can then proceed to 2524.

At 2524, the process 2500 can generate one or more child metasurface designs based on the group of metasurface designs. In some examples, the process 2500 can generate two child metasurface designs for each pair of metasurface designs included in the group of metasurface designs. In some examples, the process 2500 can randomly pair metasurfaces designs included in the group of metasurface designs without replacement, and then generate two child metasurface designs for each pair of metasurfaces. In some examples, the process 2500 can mutate each child metasurface design. In some examples, for each pair of metasurface designs, the process 2500 can mutate a first child metasurface design by individually swapping each gene included in the first child metasurface design genome with a corresponding gene from a second child metasurface design with a predetermined probability. In some examples, the process 2500 can generate a fitness score for each child metasurface design and remove lower scoring child metasurface designs. The process 2500 can then proceed to 2528.

At 2528, the process 2500 can output one or more child metasurface designs to at least one of a user interface, an external device, or the at least one non-transitory computer-readable storage medium. The process 2500 can then end. An advantage of the process 2500 is that metasurface designs can be generated without the use of differentiation and/or losses.

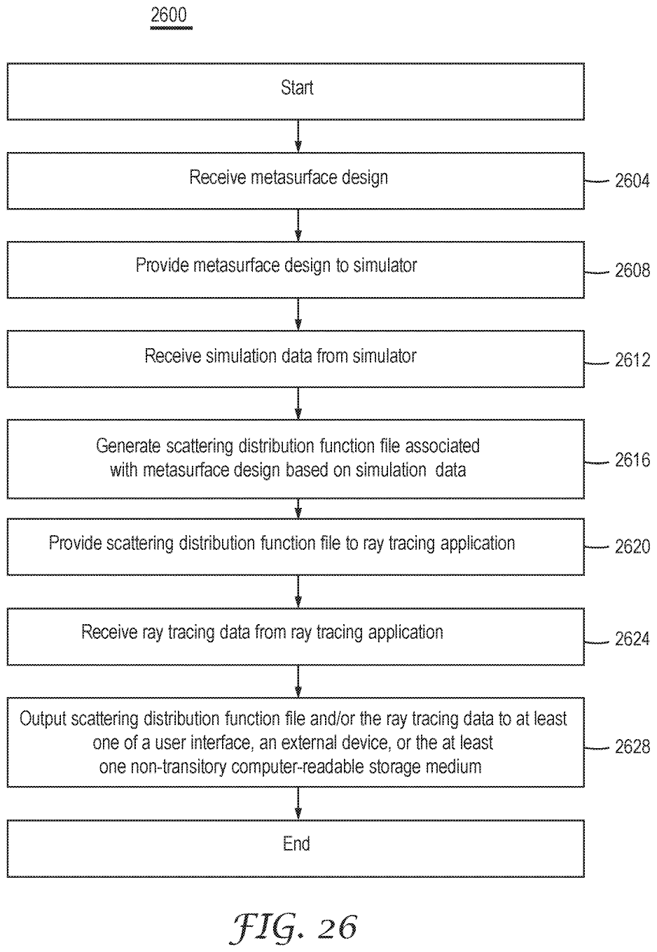

FIG. 26 illustrates an exemplary process for generating metasurface designs and associated ray tracing data according to aspects of this disclosure. In some examples, the process 2600 can be implemented in the ray tracing application 68D in FIG. 2. In some examples, the process 2600 can be implemented as instructions on at least one non-transitory computer-readable storage medium (e.g., the memory 32 in FIG. 2) and executed by one or more processors (e.g., the processors 28) coupled to the at least one non-transitory computer-readable storage medium and configured to execute the instructions.

At 2604, the process 2600 can receive a metasurface design. The process 2600 can then proceed to 2608.

At 2608, the process 2600 can provide the metasurface design to a simulator. The process 2600 can then proceed to 2612.

At 2612, the process 2600 can receive simulation data from the simulator. The simulation data can include performance information associated with the metasurface design. The process 2600 can then proceed to 2616.

At 2616, the process 2600 can generate a scattering distribution function file associated with the metasurface design based on the simulation data. The process 2600 can then proceed to 2620.

At 2620, the process 2600 can provide the scattering distribution function file to a ray tracing application. The process 2600 can then proceed to 2624.

At 2624, the process 2600 can receive ray tracing data from the ray tracing application. The process 2600 can then proceed to 2628.

At 2628, the process 2600 can output the scattering distribution function file and/or the ray tracing data to at least one of a user interface, an external device, or the at least one non-transitory computer-readable storage medium. The process 2600 can then end. An advantage of the process 2600 is that metasurface designs can be generated without the use of differentiation and/or losses.

In the present detailed description of the example embodiments, reference is made to the accompanying drawings, which illustrate specific embodiments in which the invention may be practiced. The illustrated embodiments are not intended to be exhaustive of all embodiments according to the invention. It is to be understood that other embodiments may be utilized, and structural or logical changes may be made without departing from the scope of the present invention. The following detailed description, therefore, is not to be taken in a limiting sense, and the scope of the present invention is defined by the appended claims.

Unless otherwise indicated, all numbers expressing feature sizes, amounts, and physical properties used in the specification and claims are to be understood as being modified in all instances by the term “about” or “approximately” or “substantially.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

It is to be recognized that depending on the example, certain acts or events of any of the methods described herein can be performed in a different sequence, may be added, merged, or left out altogether (e.g., not all described acts or events are necessary for the practice of the method). Moreover, in certain examples, acts or events may be performed concurrently, e.g., through multi-threaded processing, interrupt processing, or multiple processors, rather than sequentially.

The techniques described in this disclosure may be implemented, at least in part, in hardware, software, firmware or any combination thereof. For example, various aspects of the described techniques may be implemented within one or more processors, including one or more microprocessors, CPUs, GPUs, DSPs, application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry (e.g., fixed function circuitry, programmable circuitry, or any combination of fixed function circuitry and programmable circuitry), alone or in combination with other logic circuitry, or any other equivalent circuitry. A control unit comprising hardware may also perform one or more of the techniques of this disclosure.

Such hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components.

The techniques described in this disclosure may also be embodied or encoded in a computer-readable medium, such as a computer-readable storage medium, containing instructions. Instructions embedded or encoded in a computer-readable storage medium may cause a programmable processor, or other processor, to perform the method, e.g., when the instructions are executed. Computer readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer readable media.

Various examples have been described. These and other examples are within the scope of the following claims.

What is claimed is:

1. A device comprising:
at least one non-transitory computer-readable storage medium having instructions stored thereon; and
processing circuitry coupled to the at least one non-transitory computer-readable storage medium, the processing circuitry being configured to execute the instructions to:
provide randomized data to a neural network;
receive a metasurface design from the neural network, the metasurface design comprising one or more features;
provide the metasurface design to a simulator;
receive a performance value from the simulator;
determine a loss value based on the performance value;
update the neural network based on the loss value; and
output the neural network to at least one of a user interface, an external device, or the at least one non-transitory computer-readable storage medium.

2. The device of claim 1, wherein the metasurface design further comprises a raster representation of a metasurface associated with the one or more features.

3. The device of claim 1, wherein the metasurface design comprises a raster representation of a metasurface.

4. The device of claim 1, wherein the one or more features comprises two or more features.

5. The device of claim 4, wherein each feature included in the one or more features comprises size information and positional information.

6. The device of claim 4, wherein the processing circuitry is configured to further execute the instructions to:
generate a raster representation of the metasurface design based on the plurality of features; and
provide the raster representation of the metasurface design to the simulator.

7. The device of claim 4, wherein the processing circuitry is configured to further execute the instructions to:
further determine the loss value based on the two or more of features.
